(19) United States
(12) Patent Application Publication
(10) Pub. No.: US 2026/0304729 A1
(43) Pub. Date: Oct. 1, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Dian-Sheng YU, Hsinchu City (TW); Chia He CHUNG, Hsinchu City (TW); Chih-Yung LIN, Hsinchu County (TW)

(73) Assignee: TAIWAN SEMICONDUCTOR MANUFACTURING COMPANY, LTD., Hsinchu (TW)

(21) Appl. No.: 19/095,966

(22) Filed: Mar. 31, 2025

(51) Int. Cl. H10B 10/00

(52) U.S. Cl. CPC H10B 10/125; H10B 10/18

(57) ABSTRACT

A method includes forming memory cells in a memory array arranged in rows and columns over a substrate, the substrate defining a near-end bit-line region, a far-end bit-line region, a transition region between the near-end and far-end bit-line regions, and a cell edge region; forming a far-end bit-line, comprising: forming a first segment extending in the first metal layer over the far-end bit-line region to the transition region, the first segment electrically coupled to a subset of the memory cells in one of the columns of the memory array within the far-end bit-line region; forming a second segment extending in a second metal layer over the near-end bit-line region to the cell edge region, the second segment of the far-end bit-line further connecting to a bit-line of the peripheral circuit in the second metal layer along a continuous path in the second metal layer.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a static random access memory (SRAM) array layout with word lines (WL), bit-lines (BL), and complementary bit-lines (BLB), including two sub-arrays in accordance with some embodiments of the present disclosure.

FIG. 1B illustrates a schematic view of a circuit diagram in a SRAM array in accordance with some embodiments of the present disclosure.

FIG. 1C illustrates a schematic enlarged view of a region in FIG. 1B in accordance with some embodiments of the present disclosure.

FIG. 1D illustrates a schematic view of a circuit diagram of a SRAM cell in accordance with some embodiments of the present disclosure.

FIG. 1E illustrates a layout of front-end features of an SRAM cell in accordance with embodiments of the present disclosure.

FIG. 1F illustrates a perspective view of an example nano-FET device in accordance with some embodiments of the present disclosure.

FIG. 1G illustrates a schematic cross-sectional view of the layers involved in an SRAM cell array in accordance with some embodiments of the present disclosure.

FIG. 1H illustrates a schematic cross-sectional view of jump cells within the column of FIG. 1A in accordance with some embodiments of the present disclosure.

FIG. 2 illustrates a schematic division of a SRAM array layout between near-end and far-end BL configurations, including M0, M1 jumpers, and M2 hammers for BL transitions and BL connections, in accordance with some embodiments of the present disclosure.

FIG. 3A illustrates a schematic enlarged view of a region C2 in FIG. 2 with power line (Vss/Vdd) connections, showcasing the bit-line (BL) connections located in a cell edge region of a SRAM array layout for both near-end and far-end BL configurations, in accordance with some embodiments of the present disclosure.

FIGS. 3B and 3D illustrate BL connections located in the cell edge region for the near-end and far-end BL configuration, respectively, in FIG. 3A, in accordance with some embodiments of the present disclosure.

FIGS. 3C and 3E illustrate semiconductor structures corresponding to FIGS. 3B and 3D, respectively, in accordance with some embodiments of the present disclosure.

FIGS. 4A-4E illustrate BL connections in FIGS. 3A-3E in accordance with some embodiments of the present disclosure.

FIG. 5 illustrates a schematic division of a SRAM array layout between near-end and far-end BL configurations, including M1 jumpers and M2 connection for BL transitions and BL connections, in accordance with some embodiments of the present disclosure.

FIG. 6A illustrates a schematic enlarged view of a region C3 in FIG. 5 with power line (Vss/Vdd) connections, showcasing the bit-line (BL) connections located in a cell edge region of a SRAM array layout for both near-end and far-end BL configurations, in accordance with some embodiments of the present disclosure.

FIGS. 6B and 6C illustrate BL connections located in the cell edge region for the near-end and far-end BL configuration, respectively, in FIG. 6A, in accordance with some embodiments of the present disclosure.

FIGS. 7A-7C illustrate BL connections in FIGS. 6A-6C in accordance with some embodiments of the present disclosure.

FIG. 8 is a flowchart of a method forming the semiconductor structure, including BL connections of a SRAM array, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As semiconductor technology advances, achieving optimal power, performance, and area (PPA) in SRAM arrays becomes increasingly difficult, due to rising resistivity in back-end-of-line (BEOL) metal lines. These challenges may hinder memory access speeds and high-frequency bit-line operations. Therefore, to overcome these limitations, this present disclosure introduces a BEOL hybrid connection system that leverages bit-line connection structures (e.g., jumper and hammer) to enhance SRAM bit-line connections, which in turn reduces array size, minimizes metal coupling effects, and improves signal transmission speed. Additionally, by incorporating a BL transition structure that utilizes Metal-0 (e.g., metal layer M0) for near-end bit-lines and Metal-2 (e.g., metal layer M2) for far-end bit-lines, this disclosure provides a robust metal RC design window. This hybrid bit-line connection effectively addresses RC loading issues in BL transition regions, ensuring high-speed operation and reduced power consumption.

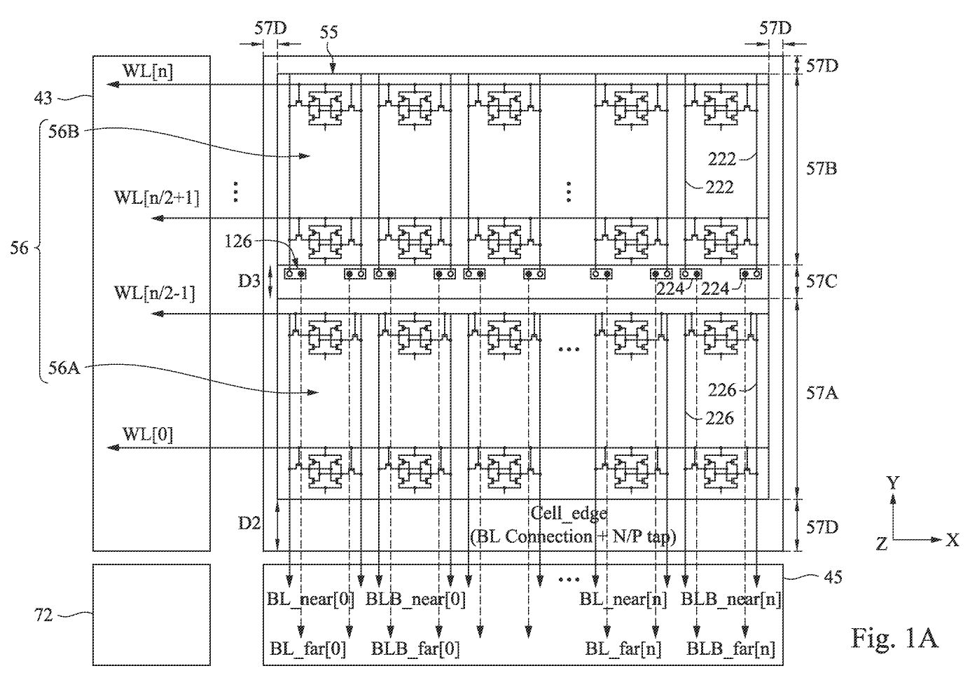

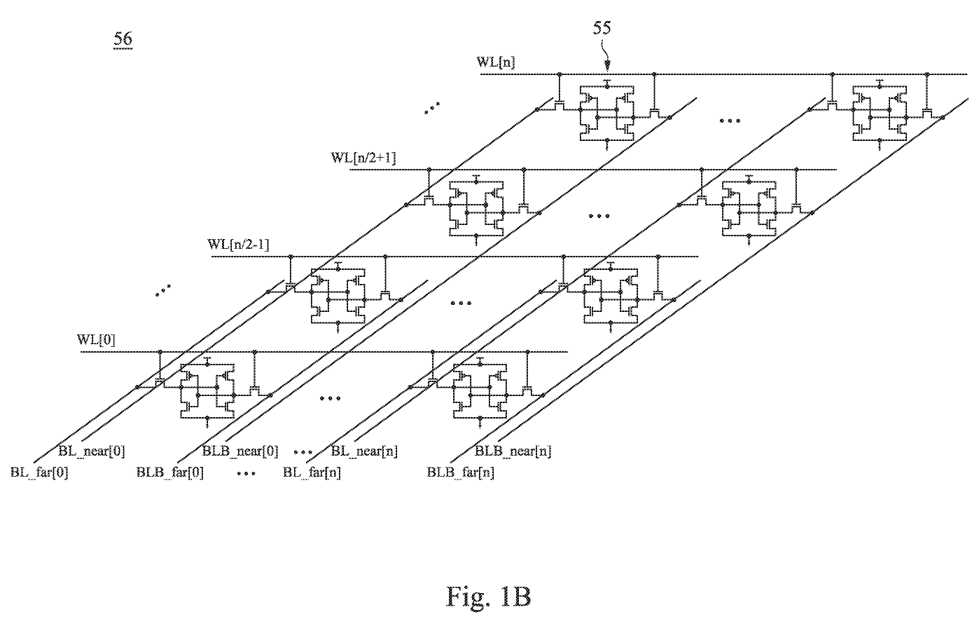

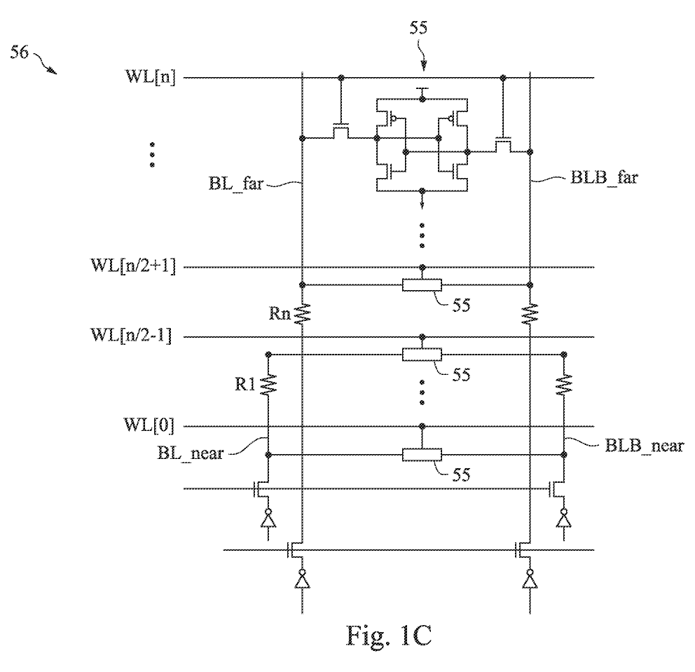

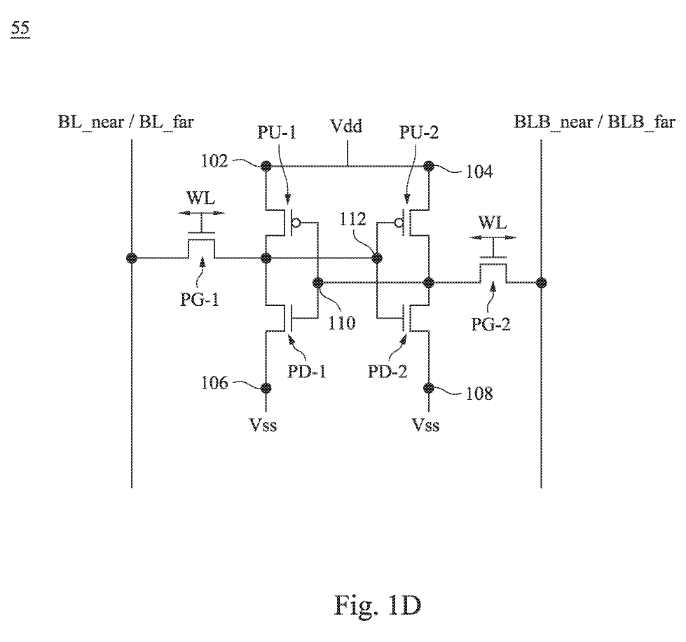

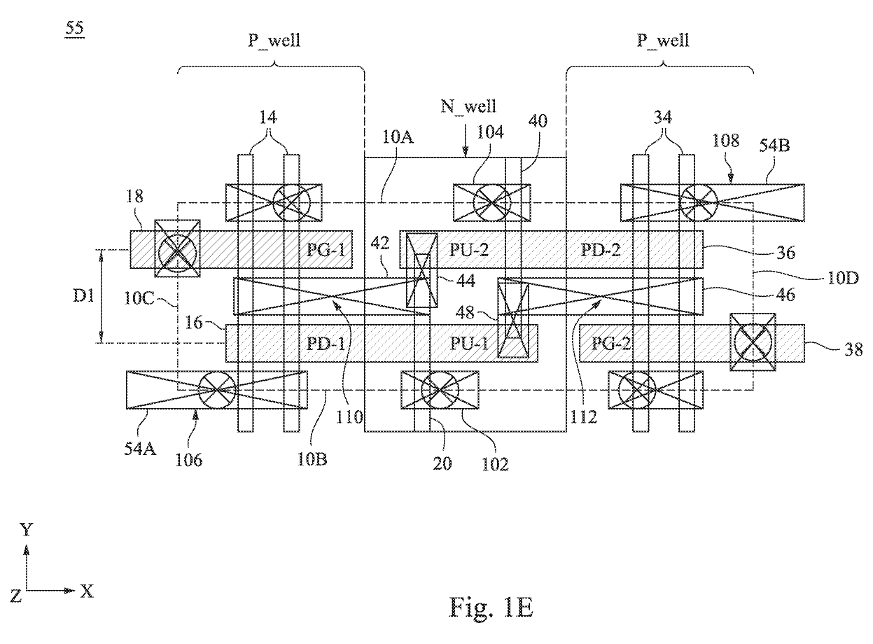

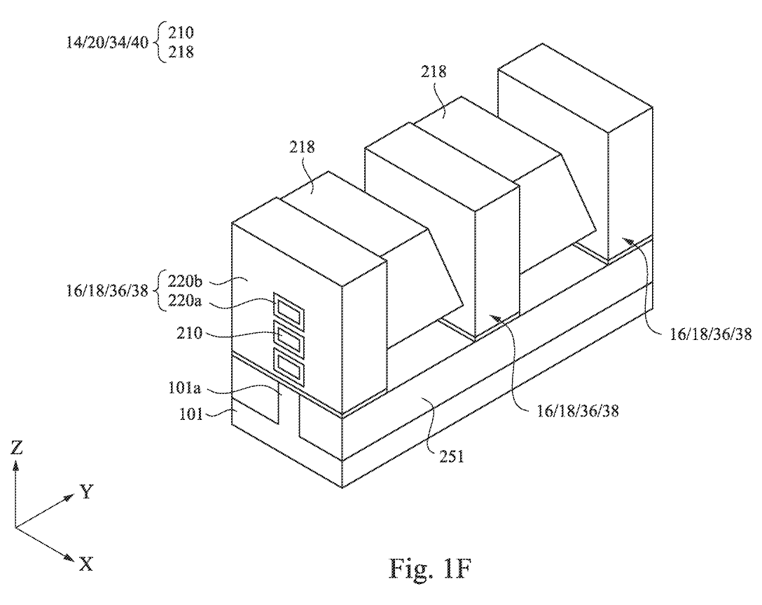

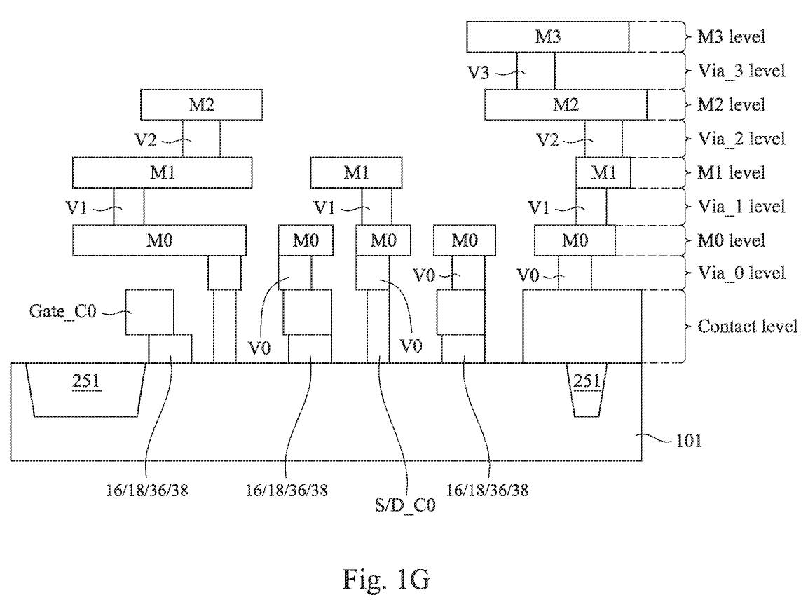

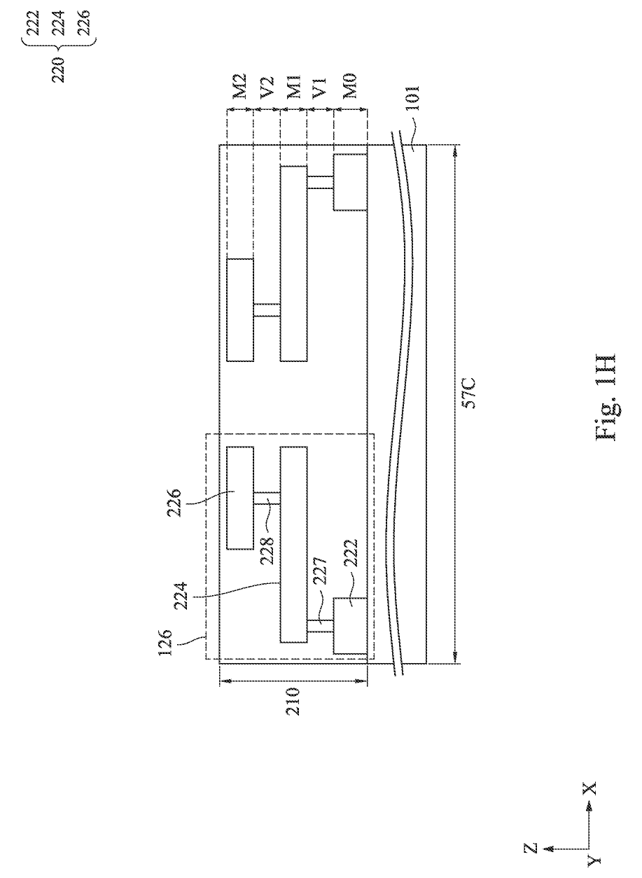

Reference is made to FIGS. 1A-1C. FIG. 1A illustrates a static random access memory (SRAM) array (e.g., SRAM array 56) layout with word lines (WL), bit-lines (BL), and complementary bit-lines (BLB), including two sub-arrays in accordance with some embodiments of the present disclosure. FIG. 1B illustrates a schematic view of a circuit diagram in a SRAM array 56 in accordance with some embodiments of the present disclosure. FIG. 1C illustrates a schematic enlarged view of a region in FIG. 1B in accordance with some embodiments of the present disclosure.

As shown in FIG. 1A, the SRAM array 56 can include two sub-arrays 56A and 56B. The SRAM array 56 can be divided into a near-end bit-line region 57A having the sub-array 56A thereon and a far-end bit-line region 57B having the sub-array 56B thereon. The near-end bit-line region 57A and the far-end bit-line region 57B can be separated by a central BL transition region 57C. The BL transition region 57C can help ensure smooth signal transitions between the sub-arrays 56A and 56B, maintaining both signal integrity and speed. The SRAM layout 56 can operate reliably even as chip sizes shrink, providing an efficient and scalable design. Bit-lines can be divided into two parts (e.g.,near-end bit-lines and far-end bit-lines), separated by a BL transition region 57C in the middle.

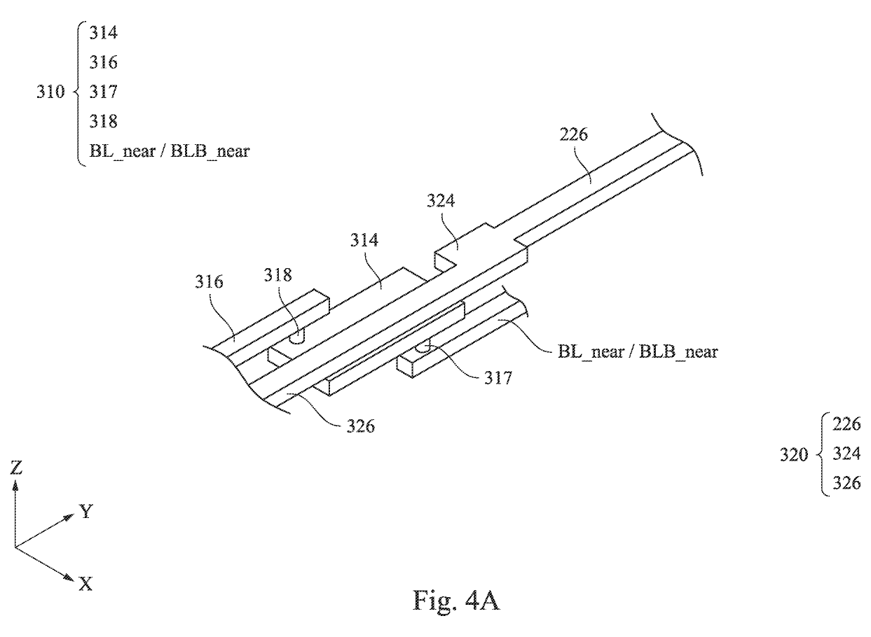

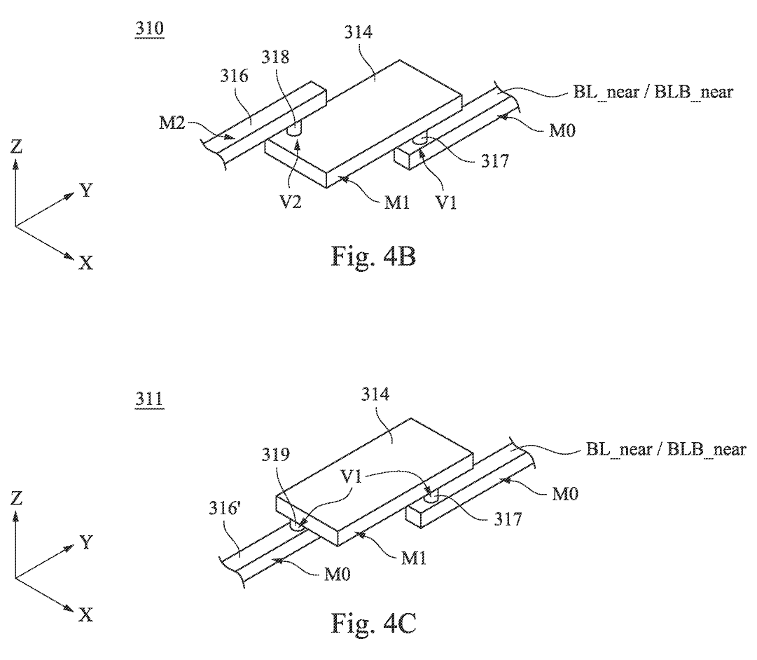

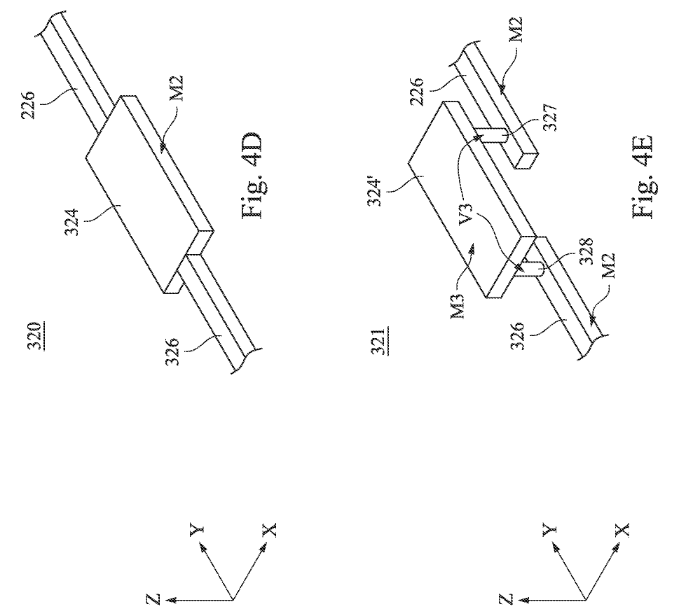

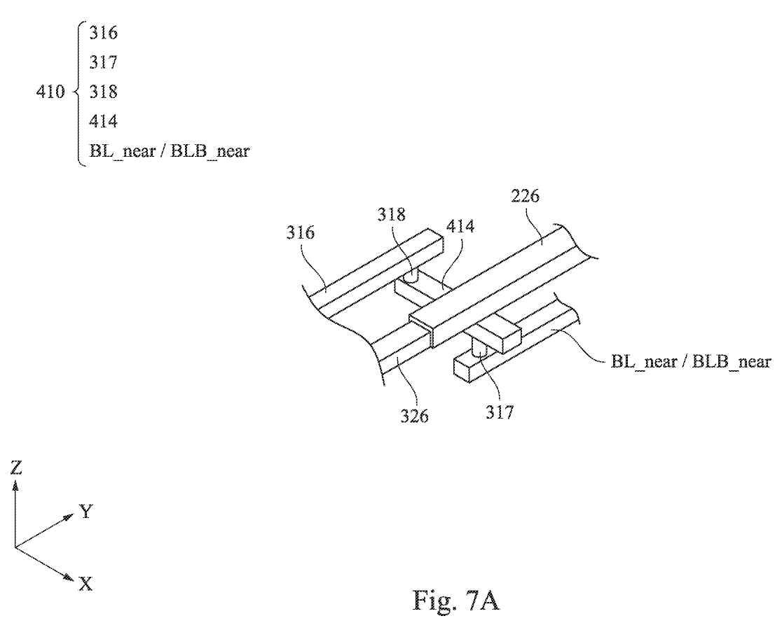

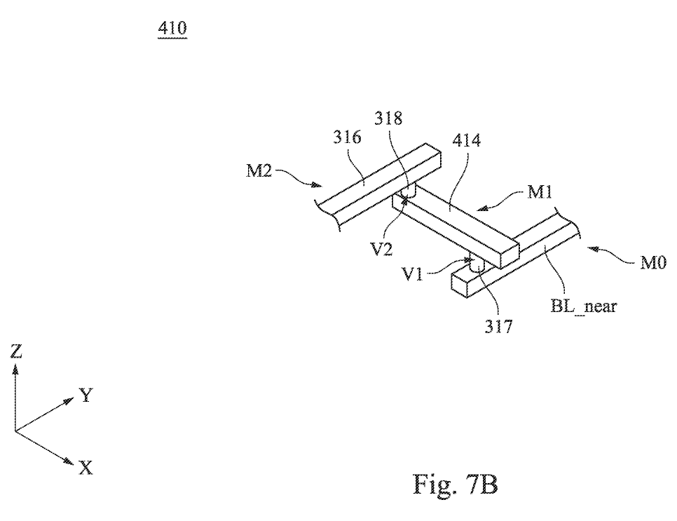

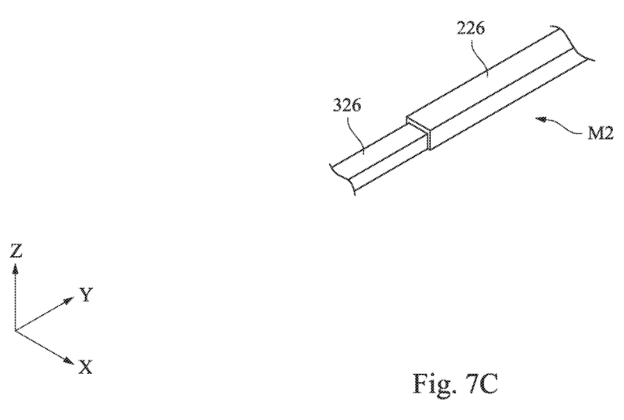

Vertical bit-lines (e.g., bit-lines BL_near[0] to BL_near[n], bit-lines BL_far[0] to BL_far[n], complementary bit-lines BLB_near[0] to complementary bit-lines BLB_near[n], and complementary bit-lines BLB_far[0] to complementary bit-lines BLB_far[n]) can carry data signals vertically through the SRAM array 56. In some embodiments, the complementary bit-lines BLB_near and BLB_far can in interchangeable referred to as bit-lines. These bit-lines are divided between two regions (e.g., near-end bit-line region 57A and far-end bit-line region 57B). In the near-end bit-line region 57A, the bit-lines BL_near[0] to BL_near[n] and their complementary bit-lines BLB_near[0] to BLB_near[n] can extend vertically in the M0 layer. The bit-lines BL_near[0] to BL_near[n] and their complementary bit-lines BLB_near[0] to BLB_near[n] remain in the M0 layer until they reach the cell edge region 57D, where they connect to peripheral circuits using, such as M1 jumpers (e.g., transition bit-line segment 314 shown in FIG. 4B) and M1 landing pads (e.g., transition bit-line segment 414 shown in FIG. 7B), allowing for shorter routing paths and faster access to stored data.

In the far-end bit-line region 57B, the bit-lines BL_far[0] to BL_far[n] and their complementary bit-lines BLB_far[0] to BLB_far[n] also start in the M0 layer. As these lines approach the BL transition region 57C, they transition to the M2 layer. This change in layer can maintain signal strength and reducing resistance over longer distances. Within the near-end bit-line region 57A, these far-end lines stay in the M2 layer as they extend toward the cell edge region 57D, where they connect to peripheral circuits via, such as M2 hammers (e.g., transition bit-line segment 324 shown in FIG. 4D), M3 jumper (e.g., transition bit-line segment 324’ shown in FIG. 4E), and direct M2 connections (see FIG. 7C). This layered approach can ensure that signals from both regions transition smoothly and maintain reliability throughout the SRAM array 56. These bit-lines can carry both data and control signals, enabling read and write operations across the SRAM array 56.

In some embodiments, M0 Layer can be the lowest metal layer in the stack, used for local routing within the SRAM cell 55, serving as the initial layer for bit-lines and complementary bit-lines in their respective regions. The M1 Layer can be the first metal layer above the M0 layer, used for, such as vertical connections and jumper structures, which in turn allows for linking local bit-lines to higher layers and peripheral circuits. The M2 Layer can be the second metal layer, used for interconnections across regions (e.g., between near-end and far-end bit-line regions) and for maintaining signal strength in longer routes. The M3 Layer can be the third metal layer, reserved for global routing and connections to external peripheral circuits.

Horizontal word lines (WL[0] to WL[n]) can extend cross the bit-lines and their complementary bit-lines at regular intervals, creating the SRAM cells 55 (see FIG. 1C) where data is stored. At every intersection of a word line and a bit-line, a SRAM cell 55 can be formed. Each SRAM cell 55 has access transistors that connect to the corresponding bit-line and complementary bit-line.

In some embodiment, an outer peripheral edge of the SRAM array 56 may be a cell edge region 57D. As shown in FIG. 1A, at the bottom of the SRAM array 56 can be the cell edge region 57D. The cell edge region 57D can include bit-line connection structures (e.g., bit-line connection structures 310, 310’, 320, 320’, and 410 shown FIGS. 4A-4E and 7A-7C) that link the bit-lines to circuits outside the array for both near-end and far-end bit-lines to improve performance. The BL transition region 57C in the SRAM array 56 can be implemented without incorporating N-/P-tap connections, simplifying its structure while maintaining its function as a transitional pathway. In contrast, the cell edge region 57D can include N-tap and P-tap connections, which provide stable electrical connections to the array's N-well and P-well, respectively. These features enhance the reliability of the SRAM design by ensuring robust well biasing and reducing leakage currents. The inclusion of N-tap and P-tap in the cell edge region 57D can further support long-term operational stability by minimizing noise and ensuring consistent electrical performance.

On the left side of the SRAM array 56, a row decoder and word line driver 43 can activate specific word lines WL[0] to WL[n] to control which SRAM cells 55 can be accessed. At the bottom, a column multiplexer (MUX) 45 can select which bit-lines send or receive signals. A control unit 72 can be connected to column multiplexer 45 and/or the row decoder and word line driver 43. The control unit 72 can provide enable control signals to operate column multiplexer 45, so that either the signals on bit-lines BL_near and BLB_near can be selected, or the signals on bit- lines BL_far and BLB_far can be selected.

In some embodiments, a dimension D3 (e.g., width) of the cell edge region 57D can be narrower than a dimension D2 (e.g., width) of the BL transition region 57C in a lengthwise direction of the bit-line segment 222/226 (or in the Y-direction). In some embodiments, the dimension D3 can be in a range from about 2-6 CPP, such as 2, 3, 4, 5, or 6 CPP. In some embodiments, the dimension D2 can be in a range from about 6-20 CPP, such as 8, 9, 10, 11, 12, 13, 14, 15, 16, 17, 18, 19, or 20 CPP. By way of example but not limiting the present disclosure, the SRAM array 56 can be compact, with planned dimensions like 10CPP (i.e., contacted poly pitch) in the cell edge region 57D and 4CPP in the BL transition region 57C. The CPP is a parameter in semiconductor design and manufacturing that measures the center-to-center distance between two adjacent contacted polysilicon gates in a transistor array.

In some embodiments, the CPP can be a metric that defines the density of transistors and determines how scalable and compact an integrated circuit can be. In some embodiments, the term "contacted poly" can refer to the polysilicon gate, which serves as the control element for current flow between the source and drain of a transistor, with "contacted" indicating the electrical connection between the polysilicon gate and the interconnect layers. The "pitch" represents the spacing between these structures, measured from the center of one gate to the center of the next, including the space for the gate itself, isolation, and any contact features. As illustrated in FIG. 1E, the SRAM cell 55 can feature a dimension D1, which represents the CPP of the SRAM cell 55.

FIG. 1B illustrates the bit-lines (e.g., bit-lines BL_near[0] to BL_near[n], BLB_near[0] to BLB_near[n], bit-lines BL_far[0] to BL_far[n], and BLB_far[0] to BLB_far[n]) and word lines (e.g., word lines WL[0] to WL[n]) can be arranged. Each SRAM cell 55 can connect to one bit-line and one complementary bit-line. The word lines can control transistors inside the SRAM cells 55, deciding when data can be read or written. Additionally, the bit-lines BL_near can be configured to connect to signals distinct from those of the bit-lines BL_far, while the bit-lines BLB_near can similarly connect to signals distinct from those of the bit-lines BLB_far. This separation in signal routing can enable independent operation of the near-end and far-end bit-lines, reducing crosstalk and minimizing signal interference across the SRAM array 56. The configuration can enhance flexibility in addressing different regions of the SRAM array 56 and allow optimized signal integrity for both read and write operations. By maintaining separate routing paths, the SRAM design can ensures lower parasitic effects and improved timing accuracy, contributing to the overall robustness and efficiency of the memory architecture.

FIG. 1C illustrates a schematic enlarged view of a region in FIG. 1B, focusing on the configurations and routing of both near-end and far-end bit-lines BL_near and BL_far and complementary bit-lines BLB_near and BLB_far as they interface with peripheral circuits. The cell edge region 57D can connect the bit-lines and complementary bit-lines to circuits outside the array, using different methods for near-end and far-end bit-lines and complementary bit-lines. The cell edge region 57D can be point where signals are transferred efficiently to ensure reliable operations across the SRAM array 56. By leveraging a multi-layered approach, including M0, M1, M2, and M3 layers, the SRAM array 56 can ensure robust signal propagation and reliable data operations across the SRAM array 56. In some embodiments, the use of N-/P-taps in the cell edge region 57 (see FIG. 1A) can stabilize electrical connections, further enhance the reliability and longevity of the SRAM array 56. The bit-lines BL_near and BL_far and complementary bit-lines BLB_near and BLB_far can handle different parts of the SRAM array 56 (e.g., sub-arrays 56A and 56B), which in turn allows for making sure each part of the SRAM array 56 works efficiently, without interfering with the other parts. Additionally, FIG. 1C illustrates resistances R1 and Rn, to represent the natural electrical load that happens in each connection. The bit-line connection structures (e.g., bit-line connection structures 310, 310’, 320, 320’, and 410 shown FIGS. 4A-4E and 7A-7C) can help reduce these resistances, making the chip faster and more reliable. By addressing these inherent limitations, the SRAM array 56 can operate efficiently under various conditions.

Reference is made to FIGS. 1D-1G. FIG. 1D illustrates a schematic view of a circuit diagram of the SRAM cell 55 in accordance with some embodiments of the present disclosure. FIG. 1E illustrates a layout of front-end features of the SRAM cell 55 in accordance with embodiments of the present disclosure. FIG. 1F illustrates a perspective view of an example nano-FET device in accordance with some embodiments of the present disclosure. FIG. 1G illustrates a schematic cross-sectional view of the layers involved in the SRAM cell array 56 in accordance with some embodiments of the present disclosure.

As shown in FIG. 1D, the SRAM cell 55 includes pull-up transistors PU-1 and PU-2, which are P-type Metal-Oxide-Semiconductor (PMOS) transistors, and pull-down transistors PD-1 and PD-2 and pass-gate transistors PG-1 and PG-2, which are N-type Metal-Oxide-Semiconductor (NMOS) transistors. The gates of pass-gate transistors PG-1 and PG-2 can be controlled by word-line WL that determines whether SRAM cell 55 is selected or not. A latch formed of pull-up transistors PU-1 and PU-2 and pull-down transistors PD-1 and PD-2 stores a bit, wherein the complementary values of the bit are stored in Storage Date (SD) node 110 and SD node 112. The stored bit can be written into, or read from, SRAM cell 55 through complementary bit-lines including bit-line BL_near/BL_far and complementary bit-line BLB_near/BLB_far. In some embodiments, the complementary bit-line can be interchangeable referred to as a bit-line bar. The SRAM cell 55 is powered through a positive power supply node Vdd that has a positive power supply voltage VDD (also denoted as Vdd). SRAM cell 55 is also connected to power supply voltage VSS (also denoted as Vss), which may be an electrical ground. Transistors PU-1 and PD-1 form a first inverter. Transistors PU-2 and PD-2 form a second inverter. The input of the first inverter is connected to transistor PG-1 and the output of the second inverter. The output of the first inverter is connected to transistor PG-2 and the input of the second inverter.

The sources of pull-up transistors PU-1 and PU-2 are connected to CVdd node 102 and CVdd node 104, respectively, which are further connected to power supply voltage (and line) Vdd. The sources pull-down transistors PD-1 and PD-2 are connected to CVss node 106 and CVss node 108, respectively, which are further connected to power supply voltage/line Vss. The gates of transistors PU-1 and PD-1 are connected to the drains of transistors PU-2 and PD-2, which form a connection node that is referred to as SD node 110. The gates of transistors PU-2 and PD-2 are connected to the drains of transistors PU-1 and PD-1, which connection node is referred to as SD node 112. A source/drain region of pass-gate transistor PG-1 is connected to the bit-line BL_near/BL_far at a BL node. A source/drain region of pass-gate transistor PG-2 is connected to the bit-line BLB_near/BLB_far at a BLB node. In some embodiments, the transistors PU-1 and PD-1 can be represented as first inverter, and the transistors PU-2 and PD-2 can be represented as second inverter. The output of first inverter can be connected to the transistor PG-1 and the input of the second inverter, and the output of the second inverter can be connected to the transistor PG-2 and the input of second inverter.

As shown in FIG. 1E, the front-end features can include the features in the Via_0 level (see FIG. 1G) and the levels underlying the Via_0 level. The outer boundaries 10A, 10B, 10C, and 10D of SRAM cell 55 are illustrated using dashed lines, which mark a rectangular region. An N_well region is at the middle of SRAM cell 55, and two P_well regions are on opposite sides of the N_Well region. CVdd node 102, CVdd node 104, CVss node 106, CVss node 108, the bit-line (BL) node, and the complementary bit-line (BLB) node, which are shown in FIG. 1D, are also illustrated in FIG. 1E. Gate structure 16 forms pull-up transistor PU-1 with the underlying active region (in the n-well region) 20. Gate structure 16 further forms pull-down transistor PD-1 with the underlying active regions 14 (in the first P_well region on the left side of the N_well region), which may be fin-based. Gate structure 18 forms pass-gate transistor PG-1 with the underlying active region 14. Gate structure 36 forms pull-up transistor PU-2 with the underlying active region 40 (in the n_well region). Gate structure 36 further forms pull-down transistor PD-2 with the underlying active region 34 (in the second P_well region on the right side of the N_well region). Gate structure 38 forms pass-gate transistor PG-2 with the underlying active region 34. In accordance with some embodiments of the present disclosure, pass-gate transistors PG-1 and PG-2, pull-up transistors PU-1 and PU-2, and pull-down transistors PD-1 and PD-2 are Fin Field-Effect Transistors (FinFETs). In accordance with alternative embodiments of the present disclosure, pass-gate transistors PG-1 and PG-2, pull-up transistors PU-1 and PU-2, and pull-down transistors PD-1 and PD-2 are planar MOS devices.

As shown in FIG. 1E, the SD node 110 includes source/drain contact plug 42 and gate contact plug 44, which are the features at the contact level (see FIG. 1G). The contact plug 42 is elongated and has a longitudinal direction in the X direction, which is parallel to the extending directions of gate structures 16 and 36. The gate contact plug 44 comprises a portion over, and is electrically connected to, gate structure 36. In accordance with some embodiments of the present disclosure, gate contact plug 44 has a longitudinal direction in the Y direction, with is perpendicular to the X direction. In the manufacturing of the SRAM cell 55 on physical semiconductor wafers, contact plugs 42 and 44 may be formed as a single continuous butted contact plug. The SD node 112 includes source/drain contact plug 46 and gate contact plug 48. The gate contact plug 48 has a portion overlapping source/drain contact plug 46. Since SD node 110 may be symmetric to SD node 112, the details of gate contact plug 48 and source/drain contact plug 46 are not repeated herein, and may be found referring to the discussion of gate contact plug 44 and source/drain contact plug 42, respectively.

FIG. 1E also illustrates word line contacts (marked as WL contacts) connected to gate structures 18 and 38. Furthermore, a plurality of vias, each illustrated using a circle and an “x” sign in the circle, is over and contacting the respective underlying contact plugs. Elongated contact plugs 54A and 54B are used to connect to the source regions of pull-down transistors PD-1 and PD-2, respectively, to CVss lines. Elongated contact plugs 54A and 54B are parts of the CVss-nodes 106 and 108, respectively. Elongated contact plugs 54A and 54B have lengthwise directions parallel to the X direction, and may be formed to overlap the corners of SRAM cell 55. Furthermore, elongated contact plugs 54A and 54B may further extend into neighboring SRAM cells that abut SRAM cell 55.

In some embodiments, the SRAM array 56 can be suited to leverage stacked nanosheet transistor technology and extreme ultraviolet (EUV) lithography technology. Stacked nanosheet transistor technology can provide a three-dimensional architecture where multiple nanosheets can be stacked vertically, allowing the SRAM cells 55 to be more compact, directly contributing to reduced array area while maintaining or even improving performance. On the other hand, the EUV lithography technology can facilitate the precise patterning for the small and intricate features of SRAM designs, allowing for tighter critical dimensions, such as the contacted poly pitch (CPP) and metal pitches, enabling denser and more uniform layouts. In the SRAM array 56, this can result in highly compact word-line and bit-line configurations for high-density SRAM arrays 56 and also ensure better layer-to-layer alignment, for the placement of elements such as the BL transition region 57C and the cell edge region 57D.

As shown in FIG. 1F, the nano-FET including in the SRAM array 56 may be nanosheet field-effect transistors (NSFETs), nanowire field-effect transistors (NWFETs), gate-all-around field-effect transistors (GAAFETs), or the like. In some embodiments, the transistor shown in FIG. 1F can include the active region 14/20/34/40 including channel regions 210 and the source/drain regions 218 on opposite sides of the channel regions 210. The transistor shown in FIG. 1F can further include a gate structure 16/18/36/38 wrapping around the channel regions 210. The gate structure 16/18/36/38 may include one or more gate electrode layer 220b and a gate dielectric layer 220a. The gate dielectric layers 220a can be formed over top surfaces of the fin strip 101a on a substrate 101 and along top surfaces, sidewalls, and bottom surfaces of the channel regions 210. The gate electrode layers 210b are formed over the gate dielectric layer 220a. A shallow trench isolation (STI) structure 251 can be formed over the substrate 101 and laterally surround the fin strip 101a. In some embodiments, the SRAM cell 55 can also be implemented using FinFET technology.

FIG. 1G illustrates a schematic cross-sectional view of a plurality of layers involved in SRAM cell 55, which layers are formed on a semiconductor chip or wafer. It is noted that FIG. 1G is schematically illustrated to show various levels of interconnect structure and transistors, and may not reflect the actual cross-sectional view of SRAM cell 55. The interconnect structure includes a contact level, an OD (wherein the term “OD” represents “active region”) level, via levels Via_0 level, Via_1 level, Via_2 level, and Via_3 level, and metal-layer levels M0 level, M1 level, M2 level, and M3 level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate contacts Gate_C0 (also referred to as contact plugs) for connecting gate electrodes of transistors (such as the illustrated exemplary transistors PU-1 and PU-2) to an overlying level such as the Via_0 level, and source/drain contacts (marked as “S/D_C0”) for connecting the source/drain regions of transistors to the overlying level.

Reference is made to FIG. 1H. FIG. 1H illustrates a schematic cross-sectional view of a jump cell 126 within the column of FIG. 1A in accordance with some embodiments of the present disclosure. As illustrated, the substrate 101 supports a BEOL interconnect structure 210 and the SRAM cell 55 (see FIG. 1A). The substrate 101 may be, for example, a bulk semiconductor substrate (e.g., a bulk silicon substrate) or a silicon-on-insulator (SOI) substrate. The BEOL interconnect structure 210 comprises a first dielectric layer 212 within which a plurality of metal layers M0, M1, M2 are alternatingly stacked with a plurality of via layers V1, V2. Further, in some embodiments, the BEOL interconnect structure 210 comprises a second dielectric layer 214 spacing the metal layer M0 from the substrate 101. In some embodiments, the metal layers M0, M1, M2 and/or the vias V1, V2 may include a metal-containing material such as titanium nitride, titanium oxide, tungsten, cobalt, ruthenium, aluminum, copper, combinations thereof, multi-layers thereof, or the like. In some embodiments, the first dielectric layers 212 and 214 may be made of an oxide, such as silicon oxide, a nitride, such as silicon nitride, the like, or a combination thereof.

As shown in FIGS. 1A and 1H, the metal layers M0, M1, M2 and the via layers V1, V2 define a set of the bit-line BL_far and the complementary bit-line BLB_far. The bit-line BL_far can include a bit-line segment 222, a transition bit-line segment 224, and a bit-line segment 226. The bit-line segment 222 can extend vertically along the Y-direction (see FIG. 1A) from the far-end bit-line region 57B to the BL transition region 57C, terminating within a jump cell 126 (see FIG. 1A). The bit-line segment 222 can play a role in routing signals from the far-end of the SRAM array 56 toward the central BL transition region 57C. The transition bit-line segment 224, within the jump cell 126, can extend horizontally along the X-direction (see FIG. 1A), connecting the bit-line segment 222 to the bit-line segment 226.

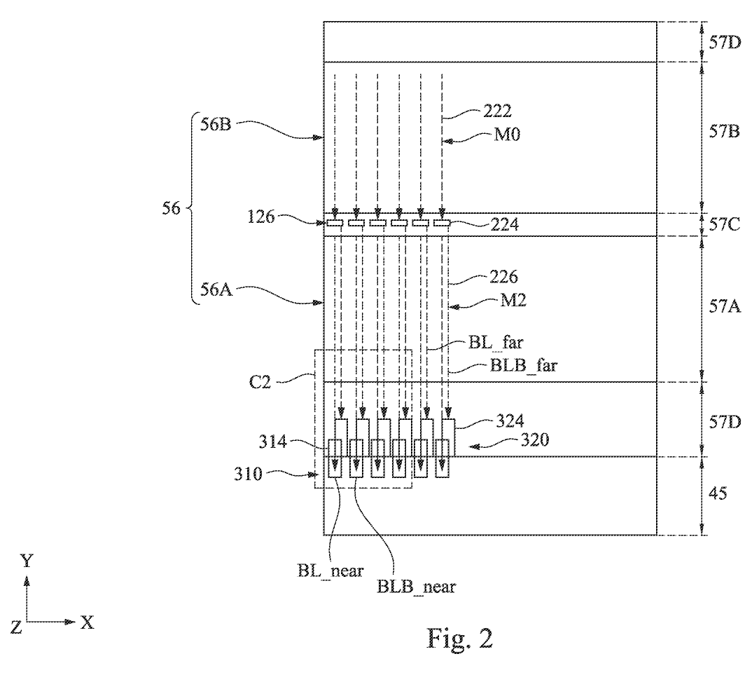

The transition bit-line segment 224 can allow for seamless routing across different segments, ensuring signal continuity and minimizing RC delays. The bit-line segment 226 can continues vertically along the Y-direction (see FIG. 1A) from the BL transition region 57C, passing through the near-end bit-line region 57A, and can extend further to the cell edge region 57D, where it connects to the bit-line connection structure (e.g., bit-line connection structure 320 shown in FIG. 4B). The bit-line segment 226, as shown in FIG. 2, can enables efficient interfacing with peripheral circuits (e.g., column multiplexer 45), maintaining signal integrity while reducing resistance and capacitance along the routing path. The configuration of these segments can ensure a smooth and reliable connection from the far-end region to the cell edge, leveraging the BL transition region 57C and its associated jump cell 126. The bit-line segment 222 can be electrically coupled to corresponding memory cells 55 within the far-end bit-line region 57B, and the bit-line segment 226 can be electrically isolated from corresponding memory cells 55 within the near-end bit-line region 57A.

In some embodiments the bit-line segment 222, the transition bit-line segment 224, and the bit-line segment 226 within the jump cell 126 can be collectively referred to as a bit-line connection structure 220, and the transition bit-line segment 224 can be interchangeable referred to as a jumper, a metal line, a line pattern, a metal layer, a landing pad, or a connection. The bit-line segment 222 and the bit-line segment 226 are in different metal layers, and the transition bit-line segment 224 is in a metal layer between these different metal layers. For example, the bit-line segment 226 may be in a M2 level layer (i.e., metal layer M2), the transition bit-line segment 224 may be in a M1 level layer (i.e., metal layer M1), and the bit-line segment 222 may be in a M0 level layer (i.e., metal layer M0). Further, the bit-lines BL_far each comprise a first via 227 and a second via 228. The first via 227 electrically couples the bit-line segment 222 to the transition bit-line segment 224 in, for example, a via_1 level layer (i.e., via V1). The second via 228 electrically coupling the transition bit-line segment 224 to the bit-line segment 226 in, for example, a via_2 level layer (i.e., via V2).

In some embodiments, the structural configuration of the complementary bit-line BLB_far is similar to that of bit-lines BL_far. Therefore, the present disclosure may repeat reference numerals and/or letters in the various examples. This repetition is for simplicity and clarity and does not dictate a relationship between the various embodiments and/or configurations discussed.

Reference is made to FIG. 2. FIG. 2 illustrates a schematic division of a SRAM array layout between near-end and far-end BL configurations, including M0, M1 jumpers, and M2 hammers for BL transitions and BL connections, in accordance with some embodiments of the present disclosure. In some embodiments, the SRAM array 56 can have high performance and reduced power consumption in advanced technology scaling through the incorporation of a BL transition region 57C located in the middle of the SRAM array 56. The BL transition region 57C can addresses bit-line (BL) resistance and capacitance (RC) loading issues by acting as a connection point to the periphery circuit, such as the column multiplexer 45 adjacent to the cell edge region 57D, as shown in FIG. 2.

By minimizing RC delays and ensuring reliable periphery connections, the BL transition region 57C can enhance the efficiency of the SRAM array 55. However, as technology nodes scale down and array dimensions shrink, connecting the BLs to the periphery circuit may present increasing challenges, particularly due to metal coupling effects and higher RC loads. To address these scaling challenges, the SRAM array 55 introduces a back-end-of-line (BEOL) hybrid connection strategy, incorporating two distinct bit-line connection structures tailored to the near-end and far-end BL configurations. For the near-end BL configuration, a jumper design, as illustrated in FIG. 4B, can be utilized as the bit-line connection structure 310. The bit-line connection structure 310 can support efficient vertical transitions, reduce RC delays, and improve overall signal speed in the near-end region. For the far-end BL configuration, a hammer design, as shown in FIG. 4D, can be utilized as the bit-line connection structure 320. The bit-line connection structure 320 can minimize resistance and capacitance, ensuring robust signal transmission over longer distances in the far-end region.

These hybrid connection structures (e.g., bit-line connection structures 310 and 320) can collectively enable the SRAM array 56 to shrink its physical footprint, reduce metal coupling effects, and achieve improved read/write speeds. Additionally, to address BL RC loading issues associated with the middle strap BL transition structure, such as the jump cell 126, a flying BL design (e.g., bit-line segment 226) has been developed. The flying bit-line segment 226 can reduce interactions between BLs and other layers, enhancing signal integrity and optimizing power consumption. Through these combined features (e.g., BL transition region 57C, BEOL hybrid connection structures, and flying bit-line segment 226), the SRAM array 56 can be equipped to overcome the challenges of technology scaling, ensuring that the SRAM array 55 can have improved performance, efficient power consumption, and reliability in high-performance applications.

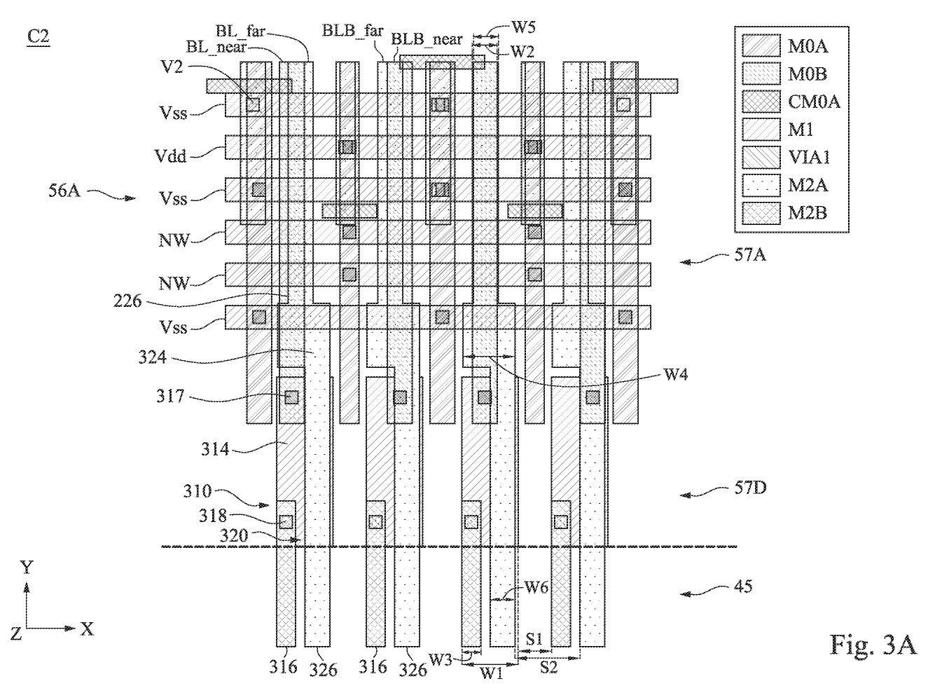

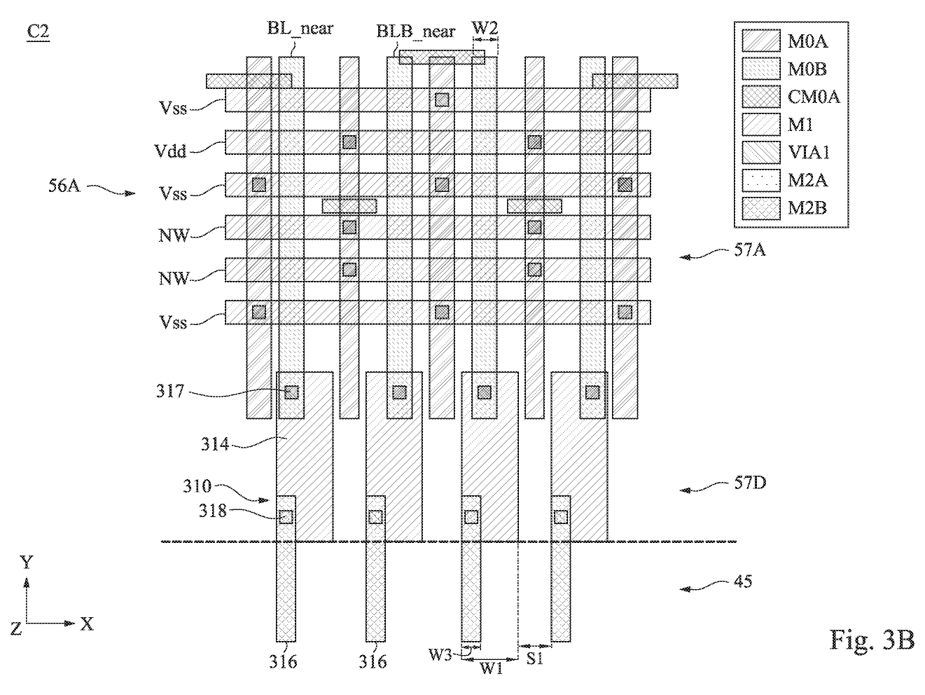

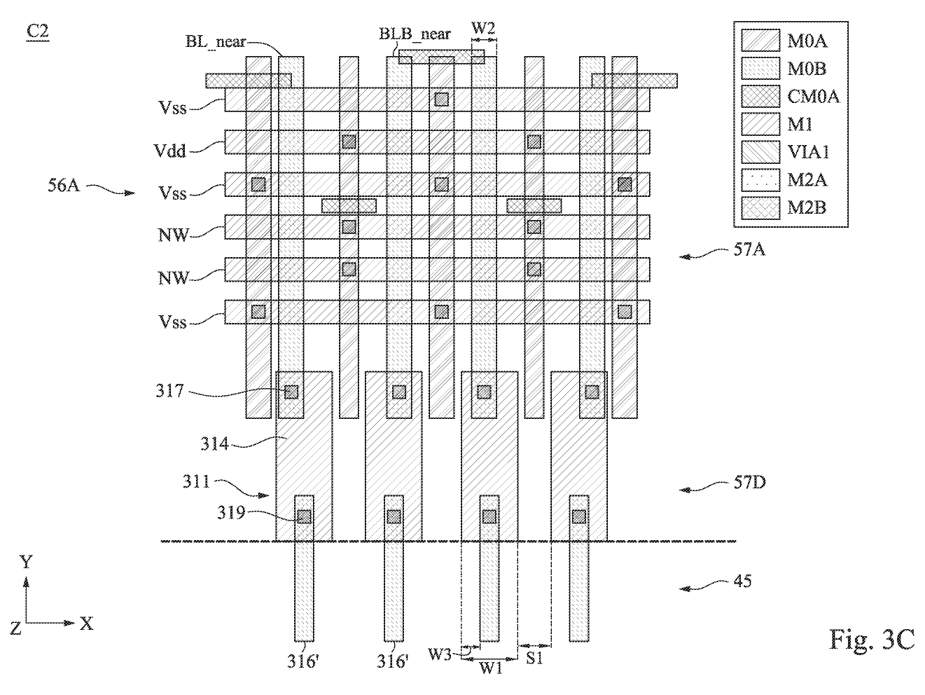

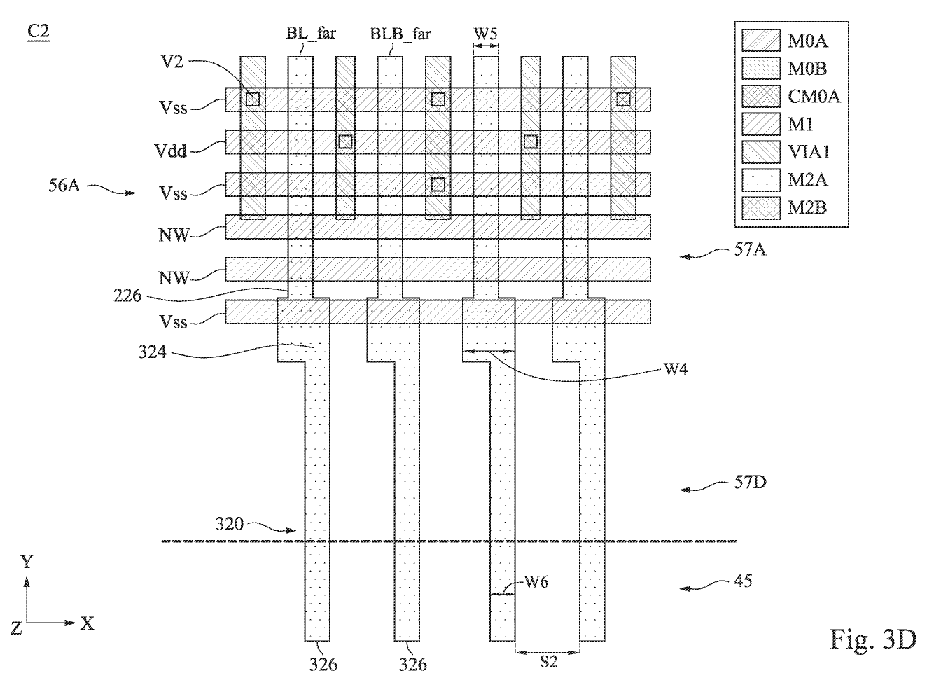

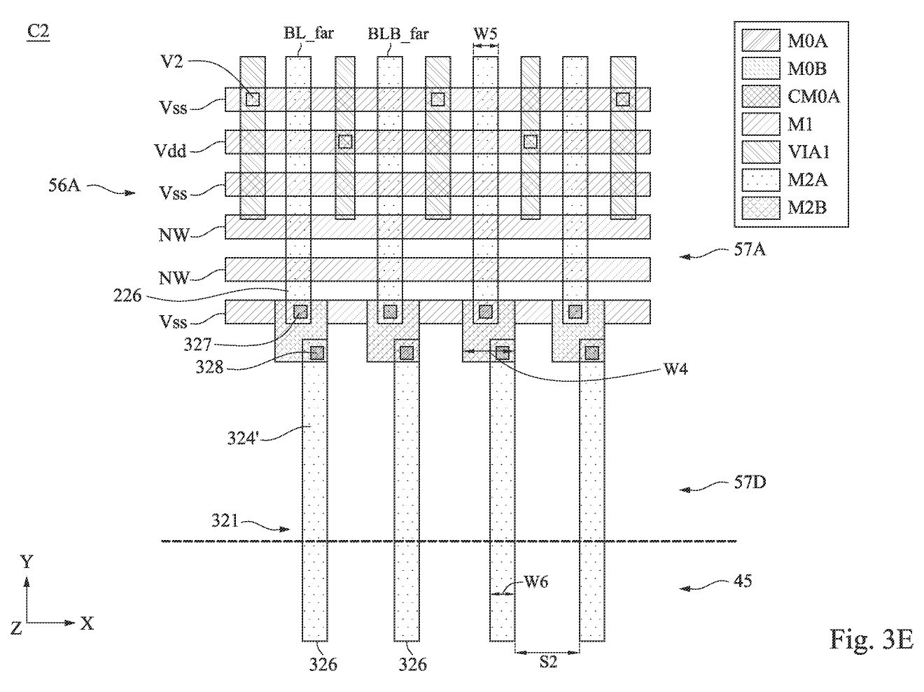

Reference is made to FIGS. 3A, 3B, 4A, and 4B. FIG. 3A illustrates a schematic enlarged view of a region C2 in FIG. 2 with power line (Vss/Vdd) connections, showcasing the bit-line (BL) connections located in a cell edge region of a SRAM array layout for both near-end and far-end BL configurations, in accordance with some embodiments of the present disclosure. FIG. 3B illustrates BL connections located in the cell edge region for the near-end and far-end BL configuration, respectively, in FIG. 3A, in accordance with some embodiments of the present disclosure. FIGS. 4A and 4B illustrate BL connections in FIGS. 3A and 3B in accordance with some embodiments of the present disclosure.

As shown in FIGS. 3A and 3B, the bit-line BL_near in the SRAM array 56 can connect to the peripheral circuit, such as bit-line 316 in the column multiplexer 45, using a transition bit-line segment 314. The transition bit-line segment 314 can ensure a seamless connection between the bit-line BL_near in the SRAM array 56 and the peripheral circuit located adjacent to the cell edge region 57D. In some embodiments, the bit-line BL_near, the transition bit-line segment 314, and the bit-line 316 within the cell edge region 57D can be collectively referred to as the bit-line connection structure 310, which is integral for robust signal routing. The bit-line connection structure 310 can also be interchangeably referred to as a periphery BL connection.

In some embodiments, the transition bit-line segment 314 can provide a reliable and scalable connection path, facilitating efficient signal transfer while supporting technology scaling. By maintaining the same width W1 (see FIGS. 3A and 3B) and space S1 (see FIGS. 3A and 3B) along the X-direction, as shown in FIGS. 3A and 3B, the transition bit-line segment 314 can ensure design consistency and alignment with manufacturing requirements. Additionally, in some embodiments, the width W1 of the transition bit-line segment 314 can be greater than the width W2 of the bit-line BL_near and the width W3 of the bit-line 316, enhancing signal integrity by reducing resistance. Furthermore, the width W2 of the bit-line BL_near can be greater than W3 of bit-line 316, allowing for an optimized transition of signals between regions.

As shown in FIGS. 3A and 3B, the transition bit-line segment 314 can extend along the Y-direction, maintaining alignment with the lengthwise direction of both bit-line BL_near and bit-line 316. This orientation can minimize cross-talk and support high-speed operation. Additionally, power lines Vss, Vdd, and NW can be included in the M1 layer (i.e., metal layer M1), extending along the X-direction and providing power delivery to the SRAM array 56. These power lines can be electrically coupled through the via_1 level layer (i.e., via V1), which establishes vertical interconnections to maintain consistent power delivery and reduce impedance.

In FIGS. 4A and 4B, the bit-line BL_near and the bit-line 316 can be located in different metal layers, with the transition bit-line segment 314 positioned in an intermediate metal layer to facilitate their connection. For instance, the bit-line 316 can be located in the M2 level layer (i.e., metal layer M2), the transition bit-line segment 314 can be located in the M1 level layer (i.e., metal layer M1), and the bit-line BL_near can be located in the M0 level layer (i.e., metal layer M0). This multi-layered arrangement can enables efficient vertical signal routing while maintaining high signal integrity.

The bit-line connection structure 310 also can incorporate vertical interconnects, such as via 317 and via 318, to establish electrical continuity between the different layers. The via 317 can electrically connect the bit-line BL_near in the M0 layer to the transition bit-line segment 314 in the M1 layer, utilizing the via_1 level layer (e.g., via V1). Similarly, via 318 can electrically connect the transition bit-line segment 314 in the M1 layer to the bit-line 316 in the M2 layer, utilizing the via_2 level layer (i.e., via V2). The vias 317 and 318 can ensure a seamless transition between layers, supporting efficient and reliable communication between the SRAM array 56 and the column multiplexer 45.

Additionally, in some embodiments, the complementary bit-line BLB_near can also use the same bit-line connection structure 310 to connect to the column multiplexer 45, ensuring consistency across both the bit-line and complementary bit-line configurations, optimizing the layout and reducing design complexity. The layered structure and use of vertical connections can provide scalability and robust functionality in SRAM.

Reference is made to FIGS. 3C and 4C. FIG. 3C illustrates a semiconductor structure corresponding to FIG. 3B, in accordance with some embodiments of the present disclosure. FIG. 4C illustrates a BL connection in FIG. 3C in accordance with some embodiments of the present disclosure. In FIGS. 3C and 4C, an alternative configuration, referred to as a bit-line connection structure 311, can be introduced. The bit-line connection structure 311 can replace the previously discussed bit-line connection structure 310 and feature a layout similar to the bit-line connection structure 310. The repeated use of reference numerals and/or letters in these embodiments is intended for simplicity and clarity, without implying a fixed relationship between the various configurations and embodiments discussed.

The distinction between the bit-line connection structure 311 and the bit-line connection structure 310 may lie in the relative positions of the bit-line BL_near, bit-line 316', and the transition bit-line segment 314. In the bit-line connection structure 311, the bit-line BL_near and the bit-line 316' can located in the same metal layer, such as the M0 level layer (i.e., metal layer M0). This contrasts with the bit-line connection structure 310, where these bit-lines occupy different metal layers. In this embodiment, the transition bit-line segment 314 can be located in a higher metal layer, such as the M1 level layer (i.e., metal layer M1).

The vertical interconnect in the bit-line connection structure 311 can be facilitated by a via 319, which electrically couples the transition bit-line segment 314 in the M1 layer to the bit-line 316' in the M0 layer through the via_1 level layer (i.e., via V1), ensuing seamless signal routing while maintaining a compact and efficient layout. By adjusting the relative positions of the bit-lines and transition bit-line segments, bit-line connection structure 311 can provide flexibility in SRAM design, allowing for optimized configurations tailored to specific performance and scaling requirements. This alternative embodiment can demonstrate the adaptability of the SRAM application, providing a range of configurations to meet the demands of advanced SRAM applications.

Reference is made to FIGS. 3A, 3D, 4A, and 4D. FIG. 3D illustrates BL connections located in the cell edge region for the near-end and far-end BL configuration, respectively, in FIG. 3A, in accordance with some embodiments of the present disclosure. FIG. 4D illustrates a BL connection in FIG. 3D in accordance with some embodiments of the present disclosure. In FIGS. 3A and 3D, the bit-line segment 226 in the SRAM array 56 can connect to the peripheral circuit, such as bit-line 326 in the column multiplexer 45, via a transition bit-line segment 324. The transition bit-line segment 324 can ensure seamless signal routing between the far-end bit-line region and the periphery. The combination of bit-line segment 226, transition bit-line segment 324, and bit-line 326 within the cell edge region 57D can be collectively referred to as the bit-line connection structure 320, which can also be interchangeably called a periphery BL connection. The bit-line segment 226 can connect to the bit-line 326 of the column multiplexer 45 in the M2 layer along a continuous path in the M2 layer.

In some embodiments, the transition bit-line segment 324 can be referred to as a hammer or a metal structure. The transition bit-line segment 324 can be located in the M2 layer, ensuring a robust connection with minimal interference and maximum signal reliability. Unlike the transition bit-line segment 314 associated with the bit-line BL_near, the transition bit-line segment 324 associated with bit-linen BL_far can be positioned farther from the column multiplexer 45, ensuring proper separation and reducing interference. In some embodiments, the transition bit-line segment 324 may overlap with the transition bit-line segment 314 to optimize routing density, while in other configurations, its footprint may avoid the column multiplexer entirely to reduce signal congestion and improve layout simplicity.

As shown in FIGS. 3A and 3D, the transition bit-line segment 324 can maintain the same width W4 and the same space S2 along the X-direction, ensuring design consistency with technology scaling, allowing for precise and efficient manufacturing while maintaining robust signal integrity. In some embodiments, the width W4 of the transition bit-line segment 324 can be greater than the width W5 of the bit-line BL_far (or bit-line segment 226) and the width W6 of the bit-line 326. However, in FIG. 3A, the width W4 of the transition bit-line segment 324 associated with the bit-line BL_far can be narrower than the width W1 of the transition bit-line segment 324 associated with the bit-line BL_near. These distinctions in width can reflect tailored design optimizations to have the improved routing and electrical performance of near-end and far-end connections. In some embodiments, the width W5 of the bit-line BL_far can be greater than the width W6 of the bit-line 326, ensuring sufficient signal capacity for the longer routing distances of the far-end bit-lines BL_far.

Additionally, the width W6 of the bit-line 326 in the column multiplexer 45 can be substantially the same as the width W3 of the bit-line 316, supporting consistency and uniformity in the periphery circuit design. The bit-line 326 can extend along the Y-direction, aligning with the lengthwise direction of the bit-line segment 226, which in turn enables efficient signal propagation and minimizes routing complexity. As illustrated in FIG. 3A, the bit-line 326 of the column multiplexer 45 can overlap with the transition bit-line segment 314 of the bit-line connection structure 310 associated with the bit-line BL_near, which in turn optimizes the use of routing space, reducing the overall layout footprint while maintaining separation and signal integrity between overlapping segments.

In some embodiments, the power lines Vss, Vdd, and NW extending along the X-direction can be electrically coupled through the via_2 level layer (i.e., via V2) and the M2 layer (i.e., metal layer M2) to maintain consistent power distribution and reduce impedance across the array. This precise coupling of power lines ensures that the SRAM array operates efficiently under high-performance demands, mitigating potential voltage drops or current losses.

In FIGS. 4A and 4D, the bit-line segment 226 of the SRAM array 56 and the bit-line 326 of the column multiplexer 45 can be located within the same metal layer, enabling direct integration and efficient signal transmission. The transition bit-line segment 324 can serve as a connection bridge between bit-line segment 226 and bit-line 326, maintaining continuity within this shared metal layer. For instance, in some embodiments, three components (e.g., bit-line segment 226, bit-line 326, and transition bit-line segment 324) can be located in the M2 level layer (i.e., metal layer M2), simplifying the routing design and reducing complexity. This arrangement can ensure that signal integrity can be preserved while minimizing the vertical interconnects like vias, which can be used for layer transitions. By keeping these components within the same layer, the bit-line connection structure 320 can optimize manufacturing processes, reduce resistance, and enhance performance.

Additionally, the complementary bit-line BLB_far can also leverage bit-line connection structure 320 to establish a reliable link to the column multiplexer 45, ensuring consistency in the design, with both bit-line and complementary bit-line configurations benefiting from the same efficient routing framework, which in turn promotes balanced signal transmission and reduces the potential for cross-talk or interference.

Reference is made to FIGS. 3E and 4E. FIG. 3E illustrates a semiconductor structures corresponding to FIG. 3D, in accordance with some embodiments of the present disclosure. FIG. 4E illustrates a BL connection in FIG. 3E in accordance with some embodiments of the present disclosure. In FIGS. 3E and 4E, an alternative configuration referred to as a bit-line connection structure 321 can be introduced. The bit-line connection structure 321 can replace the previously discussed bit-line connection structure 320 and feature a layout similar to the bit-line connection structure 320. The repeated use of reference numerals and/or letters in these embodiments is intended for simplicity and clarity, without implying a fixed relationship between the various configurations and embodiments discussed.

The distinction between the bit-line connection structure 321 and the bit-line connection structure 320 may lie in the placement of the transition bit-line segment 324’. In the bit-line connection structure 321, the transition bit-line segment 324’ can be located in a different metal layer than the metal layer housing the bit-line segment 226 and the bit-line 326. For example, the bit-line segment 226 and the bit-line 326 can be located in the M2 level layer (i.e., metal layer M2), while the transition bit-line segment 324’ can be located in the M3 level layer (i.e., metal layer M3), which can be a layer higher than metal layer M2, which in turn provides additional routing flexibility and minimizes interference between layers.

In some embodiments, the bit-line connection structure 321 can include vertical interconnects via, via 327 and via 328. The via 327 can electrically couple the bit-line segment 226 in M2 layer to the transition bit-line segment 324’ in the M3 layer, utilizing the via_3 level layer (i.e., via V3). Similarly, the via 328 can electrically couple the transition bit-line segment 324’ in the M3 layer to the bit-line 326 in the M2 layer. These inter-layer connections can ensure seamless signal transmission and maintain high performance. By employing different metal layers for the transition bit-line segment, the bit-line connection structure 321 can offer improved signal isolation, reduced cross-talk, and enhanced routing density.

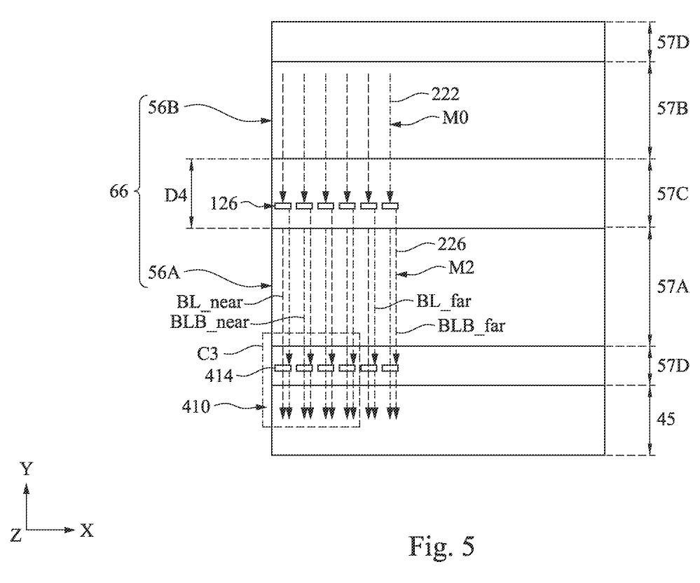

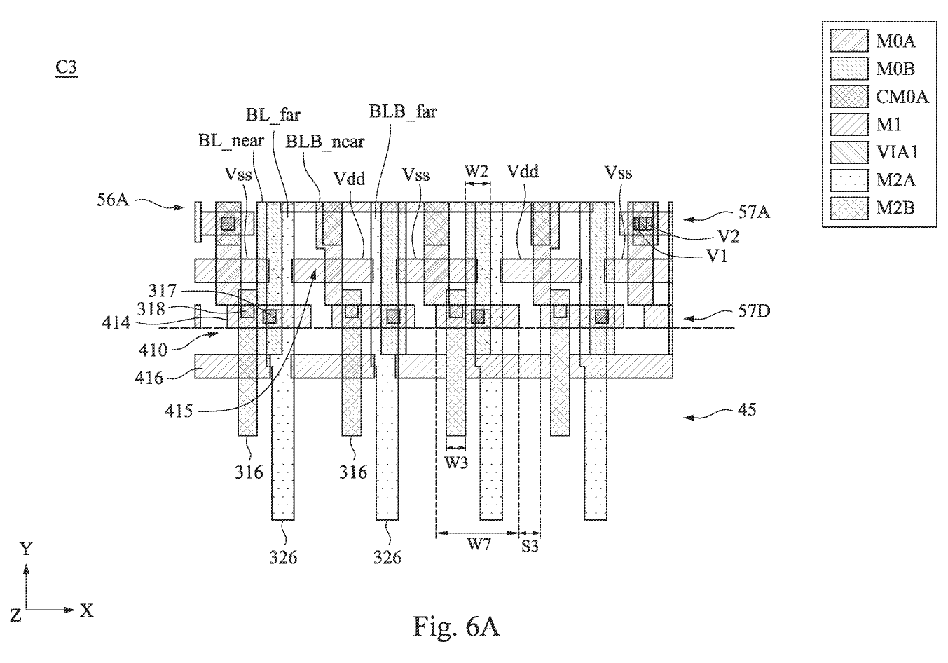

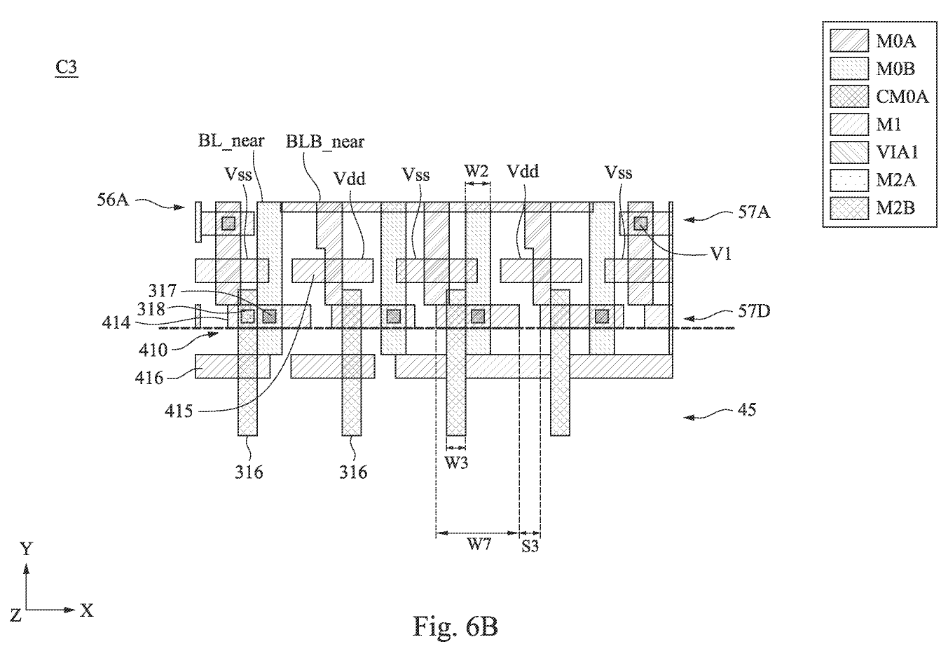

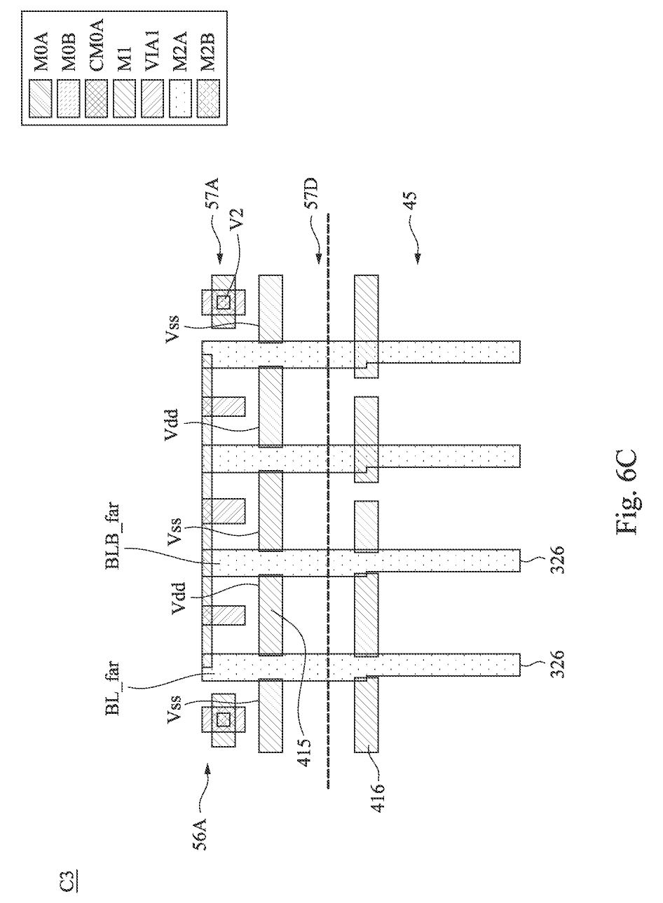

Reference is made to FIGS. 5-7C. FIG. 5 illustrates a schematic division of a SRAM array layout between near-end and far-end BL configurations, including M1 landing pad and M2 direct connection for BL connections, in accordance with some embodiments of the present disclosure. FIG. 6A illustrates a schematic enlarged view of a region C4 in FIG. 5 with power line (Vss/Vdd) connections, showcasing the bit-line (BL) connections located in a cell edge region of a SRAM array layout for both near-end and far-end BL configurations, in accordance with some embodiments of the present disclosure. FIGS. 6B and 6C illustrate BL connections located in the cell edge region for the near-end and far-end BL configuration, respectively, in FIG. 6A, in accordance with some embodiments of the present disclosure. FIGS. 7A-7C illustrate BL connections in FIGS. 6A-6C in accordance with some embodiments of the present disclosure.

While FIGS. 5-7C illustrates an embodiment of a SRAM array 66 with different configuration than the SRAM array 56 in FIGS. 2, 3A, 3B, 3D, 4A, 4B, and 4D, the present disclosure may repeat reference numerals and/or letters in the various examples. This repetition is for simplicity and clarity and does not dictate a relationship between the various embodiments and/or configurations discussed.

As shown in FIG. 5, a difference between the embodiment in FIG. 5 and the embodiment in FIG. 2 may lie in the dimensions and functionality of the BL transition region 57C. In FIG. 5, the BL transition region 57C can have a dimension D4 in the Y-direction of approximately the same as the dimension D3 of the BL transition region 57C in a lengthwise direction of the bit-line segment 222/226 (or in the Y-direction). In some embodiments, the dimension D4 can be in a range from about 6-20 CPP, such as 8, 9, 10, 11, 12, 13, 14, 15, 16, 17, 18, 19, or 20 CPP. By way of example but not limiting the present disclosure, the SRAM array 56 can be compact, with planned dimensions like 10CPP (i.e., contacted poly pitch) in the BL transition region 57C. Additionally, the BL transition region 57C in this embodiment can serve as a strap region that provides N/P-tap connections. These taps can be shared between the near-end bit-line region 57A and the far-end bit-line region 57B, ensuring robust electrical connections across the SRAM layout 56. This shared N/P-tap configuration can enhance signal stability and mitigates noise, contributing to improved overall performance and reliability of the SRAM array. The combination of compact dimensions and the integration of shared taps can demonstrate the SRAM layout 66 to have high density and efficient functionality.

In FIGS. 6A and 6B, the bit-line BL_near of the SRAM array 66 can be connected to the peripheral circuit, such as the bit-line 316 in the column multiplexer 45, via a transition bit-line segment 414. The transition bit-line segment 414 can ensure reliable and efficient signal routing between the SRAM array 66 and the peripheral circuitry adjacent to the cell edge region 57D. The combination of the bit-line BL_near, the transition bit-line segment 414, and the bit-line 316 within the cell edge region 57D can be collectively referred to as a bit-line connection structure 410, which can also be interchangeably referred to as a periphery BL connection. The transition bit-line segment 414 itself can be described interchangeably as a jumper, a metal line, a line pattern, a metal layer, a landing pad, or a connection.

The transition bit-line segment 414 can extend along the X-direction, aligning with the lengthwise direction of the word-line WL. This orientation can optimize routing and ensure that signals are transmitted efficiently across the SRAM array 66. As shown in FIGS. 6A and 6B, the transition bit-line segment 414 can maintain consistent dimensions, with a width W7 and a spacing S3 along the X-direction. This uniformity can support manufacturing consistency and alignment with technology scaling. Furthermore, the width W7 of the transition bit-line segment 414 can be greater than the width W2 of the bit-line BL_near and the width W3 of the bit-line 316, ensuring enhanced signal integrity and reduced resistance during operation.

Additionally, the M1 layer of the SRAM array 66 can incorporate a landing pad 415 for the Vss and Vdd power mesh, which further stabilizes power delivery and enhances the overall electrical performance of the SRAM array 66. The landing pads 415 can provide reliable connections for power distribution, ensuring robust operation even under high-performance conditions. Furthermore, the M1 layer of the SRAM array 66 can incorporate a dummy pad 416, which is positioned at the outermost boundary of the column multiplexer 45/the cell edge region 57D. In some embodiments, the dummy pad 416 does not serve any electrical connectivity function. Instead, it is designed to support structural integrity and alignment during the fabrication process, contributing to overall layout consistency and enhancing manufacturability. From the top view (see FIGS. 6A-6C), the dummy pad 416 can be located such that the bit-line 326 of the column multiplexer 45 and the bit-line segment 226 can extend along the Y-direction, crossing over the dummy pad 416.

In FIGS. 7A and 7B, the transition bit-line segment 414 can be located in a metal layer between the bit-line BL_near and the bit-line 316 to facilitate efficient vertical signal routing within the bit-line connection structure 410. Specifically, the transition bit-line segment 414 can be located in the M1 level layer (i.e., metal layer M1), acting as an intermediary between the bit-line BL_near in a lower metal layer and the bit-line 316 in an upper metal layer. The vertical interconnects include via 317, which electrically couples the bit-line BL_near to the transition bit-line segment 414, and via 318, which electrically couples the transition bit-line segment 414 to the bit-line 316. The vias 317 and 318 can ensure seamless signal continuity across layers, maintaining high signal integrity and minimizing resistance. The bit-line 316 of the column multiplexer 45 can connects to the transition bit-line segment 414 along the first continuous path in the M2 layer, and the bit-line 326 of the column multiplexer 45 to the bit-line segment 226 along the second continuous path in the M2 layer.

Additionally, in some embodiments, the complementary bit-line BLB_near can also utilize bit-line connection structure 410 to establish a reliable link to the column multiplexer 45, ensuring consistency in routing for both bit-line and complementary bit-line configurations, optimizing the overall layout and reducing potential interference.

In FIGS. 6A and 6C, the bit-line segment 226 of the SRAM array 66 can be directly connected to the peripheral circuit, such as the bit-line 326 in the column multiplexer 45. This direct connection can simplify the routing design and reduce additional transition segments, ensuring efficient signal transfer between the far-end bit-line region and the periphery. As shown in FIG. 6A, the bit-line segment 226 associated with the bit-line BL_far can extend across the transition bit-line segment 414 associated with the bit-line BL_near. This overlap in footprints can improve routing space, where the footprint of the bit-line segment 226 can intersect with the footprint of the transition bit-line segment 414, which in turn minimizes layout area while maintaining the integrity of both signal pathways. By adopting this approach, the SRAM array 66 can ensure robust performance and efficient layout utilization.

In FIGS. 7A and 7C, the bit-line segment 226 of the SRAM array 66 and the bit-line 326 of the column multiplexer 45 can be located within the same metal layer, facilitating a direct connection between them. For instance, both bit-line segment 226 and bit-line 326 can be located in the M2 level layer (i.e., metal layer M2), allowing for seamless signal transfer without requiring additional transition segments or vias between layers. This configuration enhances routing efficiency and reduces complexity in the SRAM design, making it well-suited for advanced scaling.

In some embodiments, the complementary bit-line BLB_far of the SRAM array 66 can also establish a direct connection to the bit-line 326 of the column multiplexer 45, mirroring the approach used for bit-line BL_far, ensuring consistent signal routing for both the bit-line and its complementary line, and maintaining balance and reducing the risk of cross-talk or signal degradation. By employing direct connections within the same metal layer, the SRAM array 66 can have improved performance and reduced resistance, in high-density SRAM arrays.

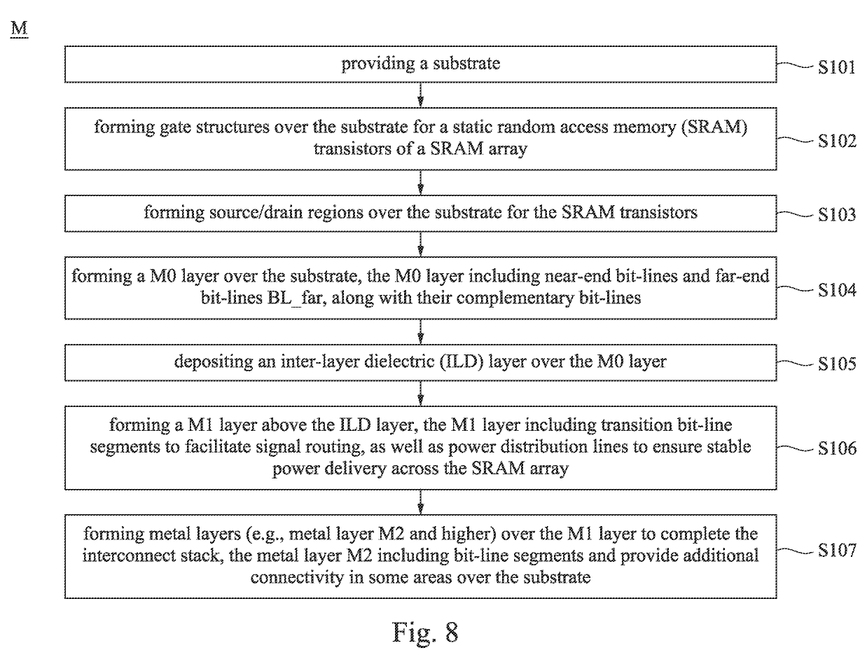

Reference is made to FIG. 8. FIG. 8 is a flowchart of a method M forming the semiconductor structure, including BL connections of a SRAM array, as illustrated in FIGS. 1A-7C, in accordance with some embodiments of the present disclosure. It is to be understood that additional operations may be performed before, during, or after the steps shown in FIGS. 1A-7C, and that some of the described steps may be replaced or omitted in other embodiments. Furthermore, the order of these operations or processes may be interchangeable, providing flexibility depending on specific requirements.

The method M initiates at block S101 a semiconductor substrate (e.g., substrate 101 illustrated in FIGS. 1F-1H) is provided. The substrate is processed to define precisely controlled N-wells and P-wells, serving as the foundational regions for the active areas of SRAM transistors. In some embodiments, advanced ion implantation techniques may be employed, utilizing multiple implantation energies and dose levels to fine-tune the well profiles. In some embodiments, shallow trench isolation (STI) structures can be formed to incorporate to electrically isolate adjacent wells.

At block S102, gate structures are formed for SRAM transistors (e.g., PU-1, PU-2, PD-1, PD-2, PG-1, and PG-2 as shown in FIG. 1E). In some embodiments, high-resolution photolithography can be employed to define the gate patterns. The gate stack may include materials such as high-k dielectrics (e.g., hafnium oxide) and metal gates (e.g., tungsten or titanium nitride). Additional techniques, such as spacer deposition and etch-back, can be performed to control the gate length and provide isolation for subsequent processes.

At block S103, source/drain (S/D) regions are formed to establish the critical electrical pathways for transistor operation. This involves employing selective epitaxial growth (SEG) to create raised S/D regions, where silicon or silicon-germanium (SiGe) can be deposited locally. In some embodiments, to further refine the junction quality, rapid thermal annealing (RTA) can be applied. This step effectively activates dopants introduced during earlier steps, repairs any crystalline damage, and ensures the formation of smooth, well-defined junctions. In some embodiments, a silicidation process can be performed, where materials like nickel or cobalt are selectively reacted with silicon in the S/D regions to form low-resistance silicide contacts. These silicide layers can minimize contact resistance, thereby improving the electrical efficiency and overall performance of the transistors.

At block S104, an M0 layer can be deposited over the substrate, serving as the foundation for local interconnects, which include near-end bit-line BL_near and far-end bit-line BL_far, along with their complementary bit-lines BLB_near and BLB_far. To achieve patterning, a dual-damascene process may be utilized, involving the sequential deposition and etching of a sacrificial dielectric, followed by metal filling. The metal layer M0 can be aligned with the SRAM layout, such as in the BL transition region 57C and the cell edge region 57D, to ensure robust electrical connectivity. In some embodiments, low-resistance materials, such as copper with barrier layers of tantalum nitride, can be used to minimize resistive losses and improve signal propagation.

At block S105, an inter-layer dielectric (ILD) layer (e.g., dielectric layer 212 in FIG. 1H) is deposited over the M0 layer to electrically isolate it from subsequent metal layers. The ILD material can be selected for its low dielectric constant (low-k), such as carbon-doped silicon oxide or advanced polymeric dielectrics, to reduce parasitic capacitance and enhance overall signal speed. In some embodiments, chemical mechanical planarization (CMP) can be performed to achieve a planar surface. In some embodiments, to enhance process reliability, the ILD deposition may incorporate multilayer stacks with etch stop layers.

At block S106, the M1 layer is deposited above the ILD layer, serving as a foundation for robust interconnects. The M1 layer can incorporate features such as transition bit-line segments (e.g., segments 224 and 314 in FIG. 3A) to facilitate signal routing, as well as power distribution lines (e.g., Vss, Vdd, and NW) to ensure stable power delivery across the SRAM array 56. To achieve these connections, vias (e.g., via 317 shown in FIG. 3A) can be formed to link the metal layers M0 and M1 at specified locations, such as for transition bit-line segments. In some embodiments, to achieve patterning, a dual-damascene process may be utilized, involving the sequential deposition and etching of a dielectric, followed by metal filling. In some embodiments, low-resistance metal materials, such as copper with barrier layers of tantalum nitride, can be used to minimize resistive losses and improve signal propagation.

At block S107, metal layers (e.g., metal layer M2 and higher) can be sequentially deposited to complete the interconnect stack. The metal layer M2 can introduce extended bit-line segments (e.g., segments 226 and 326 in FIG. 3A) and provide additional connectivity in some areas, such as the BL transition region 57C and cell edge 47D (e.g., bit-line connection structures 310, 320, and 321 in FIG. 3A). In some embodiments, the meal layers M0, M1, M2 can be patterned using cutting-edge lithographic techniques like extreme ultraviolet (EUV) lithography or multi-patterning processes, ensuring that each metal layer seamlessly integrates with the SRAM layout. In some embodiments, to support the inter-layer connectivity, additional via layers (e.g., vias V2, V3) can be created using etching and deposition techniques. These processes utilize ultra-low-k dielectrics to reduce parasitic capacitance and barrier materials to prevent metal diffusion, ensuring the long-term reliability of the interconnects.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a BEOL hybrid connection system that leverages bit-line connection structures (e.g., jumper and hammer) to enhance SRAM bit-line connections, which in turn reduces array size, minimizes metal coupling effects, and improves signal transmission speed. Additionally, by incorporating a BL transition structure that utilizes Metal-0 (e.g., metal layer M0) for near-end bit-lines and Metal-2 (e.g., metal layer M2) for far-end bit-lines, this disclosure provides a robust metal RC design window. This hybrid bit-line connection effectively addresses RC loading issues in BL transition regions, ensuring high-speed operation and reduced power consumption.

In some embodiments, a method includes forming a peripheral circuit and memory cells in a memory array arranged in rows and columns over a substrate, the substrate defining a near-end bit-line region, a far-end bit-line region, a transition region between the near-end and far-end bit-line regions, and a cell edge region, wherein in a top view, the cell edge region is between the near-end bit-line region and the peripheral circuit, and the near-end bit-line region is between the far-end bit-line region and the cell edge region; forming a near-end bit-line extending in a first metal layer over the near-end bit-line region to the cell edge region, the near-end bit-line electrically coupled to a first subset of the memory cells in one of the columns of the memory array within the near-end bit-line region; forming a first transition segment in a second metal layer at the cell edge region to electrically couple the near-end bit-line to a first bit-line of a peripheral circuit; forming a far-end bit-line, comprising: forming a first segment extending in the first metal layer over the far-end bit-line region to the transition region, the first segment electrically coupled to a second subset of the memory cells in the one of the columns of the memory array within the far-end bit-line region; forming a second segment extending in a third metal layer over the near-end bit-line region to the cell edge region, the second segment of the far-end bit-line further connecting to a second bit-line of the peripheral circuit in the third metal layer along a continuous path in the third metal layer.

In some embodiments, the second segment of the far-end bit-line is electrically isolated from the first subset of the memory cells within the near-end bit-line region. In some embodiments, the second metal layer is at an elevation higher than the first metal layer and is lower than the third metal layer. In some embodiments, the method further includes forming a second transition segment in the second metal layer at the transition region to electrically couple the first segment of the far-end bit-line to the second segment of the far-end bit-line. In some embodiments, the method further includes forming a metal structure in the third metal layer at the cell edge region, wherein the metal structure connects the second segment of the far-end bit-line to the second bit-line of the peripheral circuit, the metal structure extends lengthwise in parallel with the far-end bit-line and the second bit-line. In some embodiments, in a top view, the metal structure has a wider width than the second segment of the far-end bit-line and the second bit-line of the peripheral circuit. In some embodiments, the second segment of the far-end bit-line directly connects to the second bit-line of the peripheral circuit. In some embodiments, the first bit-line of the peripheral circuit is in the third metal layer. In some embodiments, the first bit-line of the peripheral circuit is in the first metal layer. In some embodiments, in a top view, the first transition segment has a length extending along a lengthwise direction of the near-end bit-line.

In some embodiments, a method includes forming a peripheral circuit and memory cells in a memory array arranged in rows and columns over a substrate, the substrate defining a near-end bit-line region, a far-end bit-line region, a transition region between the near-end and far-end bit-line regions, and a cell edge region, wherein in a top view, the cell edge region is between the near-end bit-line region and the peripheral circuit, and the near-end bit-line region is between the far-end bit-line region and the cell edge region; forming first far-end bit-line segments extending in a first metal layer over the far-end bit-line region to the transition region, the first far-end bit-line segments electrically coupled to a first subset of the memory cells in the columns of the memory array within the far-end bit-line region; forming transition segments in a second metal layer at the transition region, the transition segment electrically coupled to the first far-end bit-line segments, respectively; forming second far-end bit-line segments extending in a third metal layer over the near-end bit-line region to the cell edge region, the second far-end bit-line segments electrically coupled to the transition segments, respectively, and electrically isolated from a second subset of the memory cells in the columns of the memory array within the near-end bit-line region; forming metal structures in the third metal layer at the cell edge region, wherein the metal structures connect the second far-end bit-line segments to bit-lines of a peripheral circuit, respectively, wherein the metal structures extend lengthwise along a direction parallel with a lengthwise direction of the second far-end bit-line segments, and have a width greater than a width of the second far-end bit-line segments.

In some embodiments, the width of the metal structures is also greater than a width of the bit-lines of the peripheral circuit. In some embodiments, the width of the second far-end bit-line segments is greater than of the width of the bit-lines of the peripheral circuit. In some embodiments, a width of the cell edge region is narrower than a width of the transition region in a lengthwise direction of one of the first far-end bit-line segments. In some embodiments, the peripheral circuit comprises a column multiplexer.

In some embodiments, a semiconductor structure includes memory cells, a near-end bit-line, a far-end bit-line, a transition segment, and a peripheral circuit. The memory cells are in a memory array arranged in rows and columns over a substrate. The substrate defines a near-end bit-line region, a far-end bit-line region, a transition region between the near-end and far-end bit-line regions, and a cell edge region. The near-end bit-line region is between the transition region and the cell edge region. The near-end bit-line extends in a first metal layer over the near-end bit-line region to the cell edge region. The near-end bit-line is electrically coupled to a first subset of the memory cells in ones of the columns of the memory array within the near-end bit-line region. The far-end bit-line includes first and second segments. The first segment of the far-end bit-line extends in the first metal layer over the far-end bit-line region to the transition region. The first segment of the far-end bit-line is electrically coupled to a second subset of the memory cells in the one of the columns of the memory array within the far-end bit-line region. The second segment of the far-end bit-line extends in a second metal layer over the near-end bit-line region to the cell edge region. The second metal layer is at a higher elevation than the first metal layer. The transition segment is in a third metal layer at the cell edge region. The transition segment is electrically coupled to the near-end bit-line. The transition segment is at an elevation higher than the first metal layer and is lower than the second metal layer. The peripheral circuit is adjacent to the cell edge region. The peripheral circuit includes first and second bit-lines extend in the second metal layer. The first bit-line of the peripheral circuit connects to the transition segment along a first continuous path in the second metal layer. The second bit-line of the peripheral circuit connects to the second segment of the far-end bit-line along a second continuous path in the second metal layer.

In some embodiments, in a top view, the transition segment extends in a direction perpendicular to a lengthwise direction of the near-end bit-line. In some embodiments, the second bit-line of the peripheral circuit directly connects to the second segment of the far-end bit-line. In some embodiments, in a top view, the second bit-line of the peripheral circuit has a narrower width than the second segment of the far-end bit-line. In some embodiments, a width of the cell edge region is substantially the same a width of the transition region in a lengthwise direction of the near-end bit-line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a peripheral circuit and memory cells in a memory array arranged in rows and columns over a substrate, the substrate defining a near-end bit-line region, a far-end bit-line region, a transition region between the near-end and far-end bit-line regions, and a cell edge region, wherein in a top view, the cell edge region is between the near-end bit-line region and the peripheral circuit, and the near-end bit-line region is between the far-end bit-line region and the cell edge region;
forming a near-end bit-line extending in a first metal layer over the near-end bit-line region to the cell edge region, the near-end bit-line electrically coupled to a first subset of the memory cells in one of the columns of the memory array within the near-end bit-line region;
forming a first transition segment in a second metal layer at the cell edge region to electrically couple the near-end bit-line to a first bit-line of the peripheral circuit; and
forming a far-end bit-line, comprising:
forming a first segment extending in the first metal layer over the far-end bit-line region to the transition region, the first segment electrically coupled to a second subset of the memory cells in the one of the columns of the memory array within the far-end bit-line region; and
forming a second segment extending in a third metal layer over the near-end bit-line region to the cell edge region, the second segment of the far-end bit-line further connecting to a second bit-line of the peripheral circuit in the third metal layer along a continuous path in the third metal layer.

2. The method of claim 1, wherein the second segment of the far-end bit-line is electrically isolated from the first subset of the memory cells within the near-end bit-line region.

3. The method of claim 1, wherein the second metal layer is at an elevation higher than the first metal layer and is lower than the third metal layer.

4. The method of claim 1, further comprising:
forming a second transition segment in the second metal layer at the transition region to electrically couple the first segment of the far-end bit-line to the second segment of the far-end bit-line.

5. The method of claim 1, further comprising:
forming a metal structure in the third metal layer at the cell edge region, wherein the metal structure connects the second segment of the far-end bit-line to the second bit-line of the peripheral circuit, the metal structure extends lengthwise in parallel with the far-end bit-line and the second bit-line.

6. The method of claim 5, wherein, in a top view, the metal structure has a wider width than the second segment of the far-end bit-line and the second bit-line of the peripheral circuit.

7. The method of claim 1, wherein the second segment of the far-end bit-line directly connects to the second bit-line of the peripheral circuit.

8. The method of claim 1, wherein the first bit-line of the peripheral circuit is in the third metal layer.

9. The method of claim 1, wherein the first bit-line of the peripheral circuit is in the first metal layer.

10. The method of claim 1, wherein, in a top view, the first transition segment has a length extending along a lengthwise direction of the near-end bit-line.

11. A method, comprising:
forming a peripheral circuit and memory cells in a memory array arranged in rows and columns over a substrate, the substrate defining a near-end bit-line region, a far-end bit-line region, a transition region between the near-end and far-end bit-line regions, a cell edge region, wherein in a top view, the cell edge region is between the near-end bit-line region and the peripheral circuit, and the near-end bit-line region is between the far-end bit-line region and the cell edge region;
forming first far-end bit-line segments extending in a first metal layer over the far-end bit-line region to the transition region, the first far-end bit-line segments electrically coupled to a first subset of the memory cells in the columns of the memory array within the far-end bit-line region;
forming transition segments in a second metal layer at the transition region, the transition segment electrically coupled to the first far-end bit-line segments, respectively;
forming second far-end bit-line segments extending in a third metal layer over the near-end bit-line region to the cell edge region, the second far-end bit-line segments electrically coupled to the transition segments, respectively, and electrically isolated from a second subset of the memory cells in the columns of the memory array within the near-end bit-line region; and
forming metal structures in the third metal layer at the cell edge region, wherein the metal structures connect the second far-end bit-line segments to bit-lines of the peripheral circuit, respectively, wherein the metal structures extend lengthwise along a direction parallel with a lengthwise direction of the second far-end bit-line segments, and have a width greater than a width of the second far-end bit-line segments.

12. The method of claim 11, wherein the width of the metal structures is also greater than a width of the bit-lines of the peripheral circuit.

13. The method of claim 11, wherein the width of the second far-end bit-line segments is greater than of the width of the bit-lines of the peripheral circuit.

14. The method of claim 11, wherein a width of the cell edge region is narrower than a width of the transition region in a lengthwise direction of one of the first far-end bit-line segments.

15. The method of claim 11, wherein the peripheral circuit comprises a column multiplexer.

16. A semiconductor structure, comprising:
memory cells in a memory array arranged in rows and columns over a substrate, the substrate defining a near-end bit-line region, a far-end bit-line region, a transition region between the near-end and far-end bit-line regions, and a cell edge region, wherein the near-end bit-line region is between the transition region and the cell edge region;
a near-end bit-line extending in a first metal layer over the near-end bit-line region to the cell edge region, the near-end bit-line electrically coupled to a first subset of the memory cells in one of the columns of the memory array within the near-end bit-line region;
a far-end bit-line comprising:
a first segment extending in the first metal layer over the far-end bit-line region to the transition region, the first segment electrically coupled to a second subset of the memory cells in the one of the columns of the memory array within the far-end bit-line region; and
a second segment extending in a second metal layer over the near-end bit-line region to the cell edge region, the second metal layer being at a higher elevation than the first metal layer;
a transition segment in a third metal layer at the cell edge region, the transition segment electrically coupled to the near-end bit-line and being at an elevation higher than the first metal layer and lower than the second metal layer; and
a peripheral circuit adjacent to the cell edge region, the peripheral circuit comprising first and second bit-lines extending in the second metal layer,
wherein the first bit-line of the peripheral circuit connects to the transition segment along a first continuous path in the second metal layer, and the second bit-line of the peripheral circuit connects to the second segment of the far-end bit-line along a second continuous path in the second metal layer.

17. The semiconductor structure of claim 16, wherein, in a top view, the transition segment extends in a direction perpendicular to a lengthwise direction of the near-end bit-line.

18. The semiconductor structure of claim 16, wherein the second bit-line of the peripheral circuit directly connects to the second segment of the far-end bit-line.

19. The semiconductor structure of claim 16, wherein, in a top view, the second bit-line of the peripheral circuit has a narrower width than the second segment of the far-end bit-line.

20. The semiconductor structure of claim 16, wherein a width of the cell edge region is substantially the same a width of the transition region in a lengthwise direction of the near-end bit-line.
